(19) United States
(12) Patent Application Publication
(10) Pub. No.: US 2025/0275337 A1
(43) Pub. Date: Aug. 28, 2025

(54) Display Device

(71) Applicant: LG Display Co., Ltd., Seoul (KR)

(72) Inventors: Hanchul Park, Goyang-si (KR); WonJun Choi, Paju-si (KR); Gwangmin Yeo, Goyang-si (KR); Jongchan Lee, Seoul (KR)

(21) Appl. No.: 19/000,990

(22) Filed: Dec. 24, 2024

(30) Foreign Application Priority Data
Feb. 27, 2024 (KR) 10-2024-0028384

(51) Int. Cl. H10H 29/49; H01L 25/075; H01L 25/16; H10H 29/80

(52) U.S. Cl. CPC H10H 29/49; H01L 25/0753; H01L 25/167; H10H 29/8325; H10H 29/942

(57) ABSTRACT

A display device comprises top pads on a first substrate; bottom pads below a second substrate; side lines on a side surface of the first substrate and a side surface of the second substrate; and ground pads in first edges of the first substrate and the second substrate, wherein each of the top pads and the bottom pads includes: first pads in first pad areas of the first edges of the first substrate and the second substrate; and second pads in second pad areas of second edges of the first substrate and the second substrate, a high potential voltage is applied to the first pads and a low potential voltage is applied to the second pads, and the ground pads are in the first edges of the first substrate and the second substrate to be spaced apart from each other with the first pads therebetween. Therefore, overcurrent is suppressed.

### CROSS-REFERENCE TO RELATED APPLICATION

This application claims the priority of Republic of Korea Patent Application No. 10-2024-0028384 filed on Feb. 27, 2024, which is hereby incorporated by reference in its entirety.

### BACKGROUND

### Field

The present disclosure relates to a display device, and more particularly, to a display device using a light emitting diode (LED).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance can be displayed.

### SUMMARY

An object to be achieved by the present disclosure is to provide a display device with an improved reliability.

Another object to be achieved by the present disclosure is to provide a display device which suppresses a short-circuit problem by dissipating static electricity.

Still another object to be achieved by the present disclosure is to provide a display device which earths static electricity generated on a rear surface.

Objects of the present disclosure are not limited to the above-mentioned objects, and other objects, which are not mentioned above, can be clearly understood by those skilled in the art from the following descriptions.

According to an embodiment of the present disclosure, there is provided a display device. The display device comprises a first substrate; a plurality of top pads disposed on the first substrate; a second substrate disposed below the first substrate; a plurality of bottom pads disposed below the second substrate; a plurality of side lines which is disposed on a side surface of the first substrate and a side surface of the second substrate to connect the plurality of top pads and the plurality of bottom pads; and a plurality of ground pads which is disposed in a first edge of the first substrate and a first edge of the second substrate, wherein the plurality of top pads includes: a plurality of first pads disposed in a first pad area of the first edge of the first substrate; and a plurality of second pads disposed in a second pad area of a second edge of the first substrate, the plurality of bottom pads includes: a plurality of first pads disposed in a first pad area of the first edge of the second substrate; and a plurality of second pads disposed in a second pad area of a second edge of the second substrate, wherein a high potential voltage is applied to the plurality of first pads of the plurality of top pads and the plurality of bottom pads and a low potential voltage is applied to the plurality of second pads of the plurality of top pads and the plurality of bottom pads, and the plurality of ground pads is disposed in the first edge of the first substrate and the first edge of the second substrate to be spaced apart from each other with the plurality of first pads of the plurality of top pads and the plurality of bottom pads therebetween.

Other detailed matters of the exemplary embodiments are included in the detailed description and the drawings.

According to the present disclosure, a static electricity generation problem may be suppressed by improving a structure of the pad unit.

According to the present disclosure, an overcurrent is suppressed from flowing in the display device to improve the reliability of the display device.

According to the present disclosure, a static electricity discharging path is formed to improve a burnt phenomenon of a display device.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is an enlarged plan view of a first substrate of a display device according to an exemplary embodiment of the present disclosure;

FIG. 4 is an enlarged plan view of a second substrate of a display device according to an exemplary embodiment of the present disclosure;

FIG. 5 is a cross-sectional view of a sub pixel of a display device according to an exemplary embodiment of the present disclosure;

FIG. 6 is a cross-sectional view of a pad area of a display device according to an exemplary embodiment of the present disclosure;

FIG. 7A is a cross-sectional view of a top pad of a display device according to an exemplary embodiment of the present disclosure;

FIG. 7B is a cross-sectional view of a bottom pad of a display device according to an exemplary embodiment of the present disclosure;

FIG. 8 is a cross-sectional view of a ground pad of a display device according to an exemplary embodiment of the present disclosure;

FIG. 9 is a cross-sectional view of a second substrate taken along line A-A′ of FIG. 4 according to an exemplary embodiment of the present disclosure; and

FIG. 10 is a cross-sectional view of a second substrate taken along lines B-B′ and C-C′ of FIG. 4 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

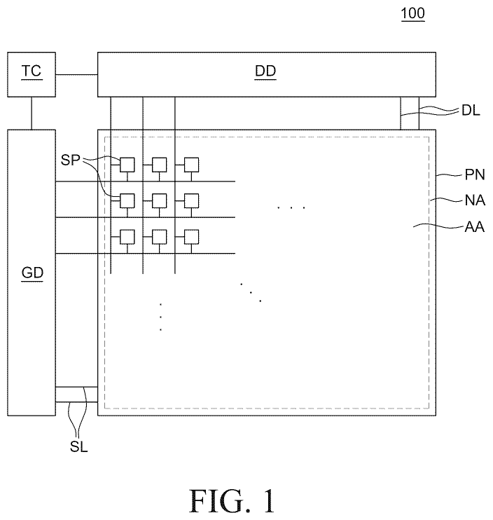

FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is configured to display images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configure a plurality of pixels PX and a circuit for driving the plurality of sub pixels SP may be disposed. The plurality of sub pixels SP are a minimum unit which configures the active area AA and n sub pixels SP may form one pixel PX. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro-LED).

In the active area AA, a plurality of signal lines which transmit various signals to the plurality of sub pixels SP are disposed. For example, the plurality of signal lines may include a plurality of data lines DL which respectively supply a data voltage to the plurality of sub pixels SP, a plurality of scan lines SL which respectively supply a gate voltage to the plurality of sub pixels SP, and the like. The plurality of scan lines SL extend to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed. The non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board and may be electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, a bezel may be increased.

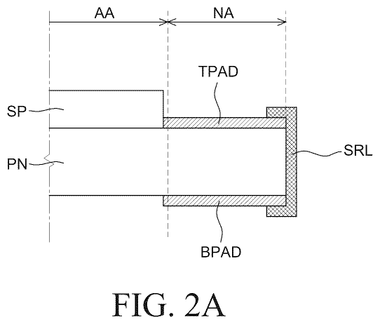

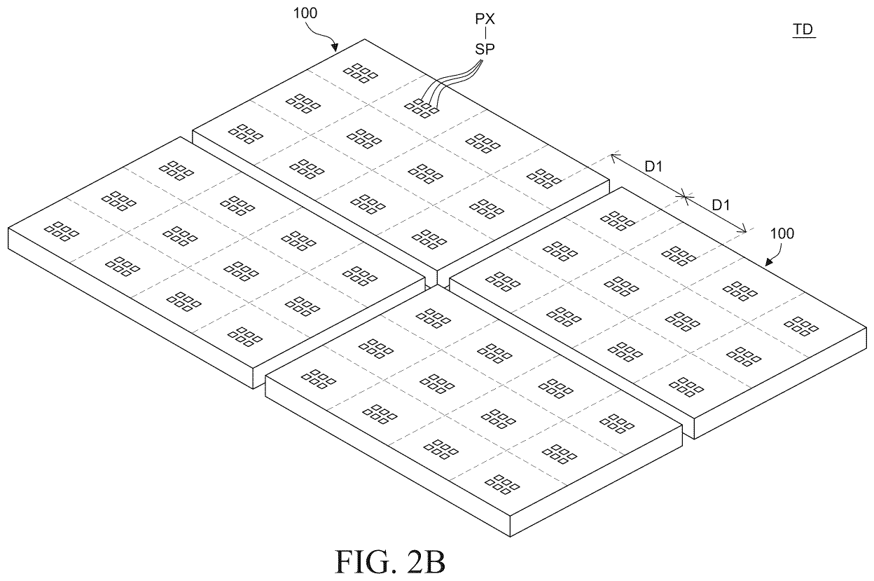

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP are disposed. For example, in a non-active area NA on the front surface of the display panel PN, a top pad TPAD which transmits a signal to the plurality of sub pixels SP is disposed. In a non-active area NA on the rear surface of the display panel PN, a bottom pad BPAD which is electrically connected to a driving component, such as a flexible film and the printed circuit board, is disposed.

In this case, even though it is not illustrated in the drawing, various signal lines connected to the plurality of sub pixels SP, for example, a scan line SL, a data line DL, or the like extends from the active area AA to the non-active area NA to be electrically connected to the top pad TPAD.

The side line SRL is disposed along a side surface of the display panel PN. The side line SRL may electrically connect the top pad TPAD on the front surface of the display panel PN and the bottom pad BPAD on the rear surface of the display panel PN. Therefore, a signal from a driving component on the rear surface of the display panel PN may be transmitted to the plurality of sub pixels SP through the bottom pad BPAD, the side line SRL, and the top pad TPAD. Accordingly, a signal transmitting path from the front surface of the display panel PN to the side surface and the rear surface is formed to minimize an area of the non-active area NA of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the exemplary embodiment of the present disclosure may be a general display device with a bezel, but is not limited thereto.

In the meantime, the display panel PN may include a first substrate and a second substrate.

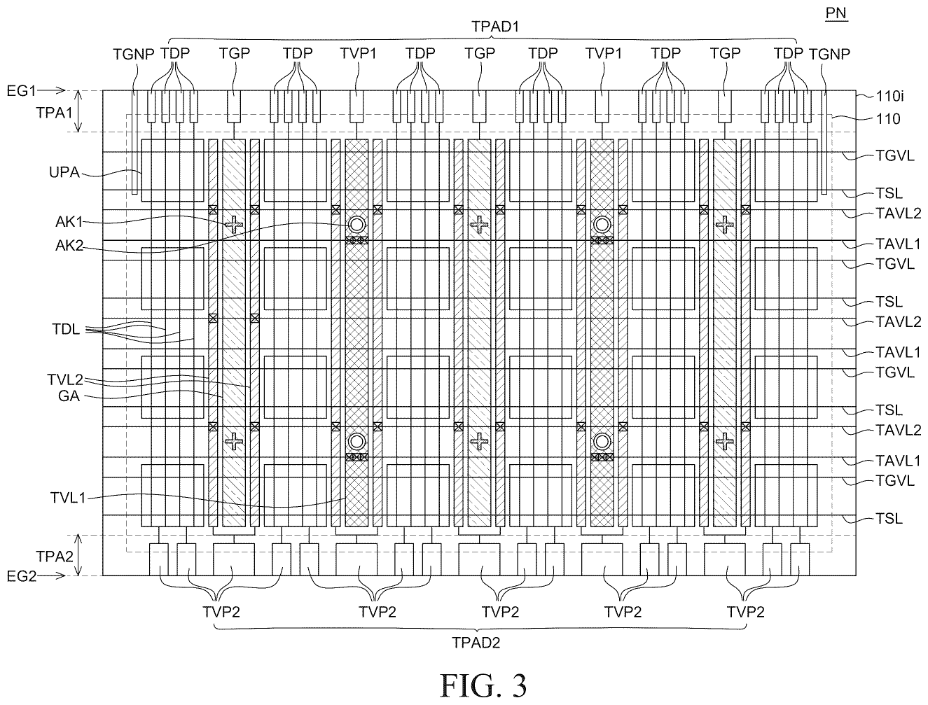

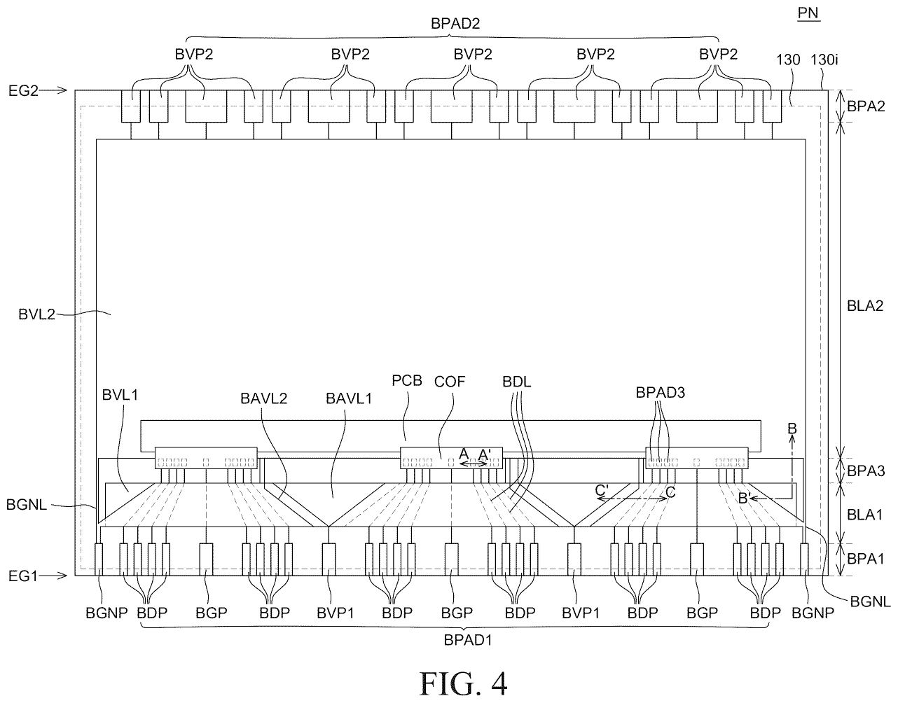

Hereinafter, the first substrate and the second substrate will be described in detail with reference to FIGS. 3 and 4.

FIG. 3 is an enlarged plan view of a first substrate of a display device according to an exemplary embodiment of the present disclosure.

First, the display panel PN includes a first substrate 110. The first substrate 110 is a substrate which supports components disposed above the display device 100 and may be an insulating substrate. A plurality of pixels PX are formed on the first substrate 110 to display images. For example, the first substrate 110 may be formed of glass or resin. Further, the first substrate 110 may include polymer or plastic. In some exemplary embodiments, the first substrate 110 may be formed of a plastic material having flexibility.

Referring to FIG. 3, in the first substrate 110, a plurality of pixel areas UPA, a plurality of gate driving areas GA, and a plurality of top pad areas are disposed. Among them, the plurality of pixel areas UPA and the plurality of gate driving areas GA may be included in the active area AA of the display panel PN.

First, the plurality of pixel areas UPA are areas in which the plurality of pixels PX is disposed. The plurality of pixel areas UPA may be disposed while forming a plurality of rows and a plurality of columns. Each of the plurality of pixels PX disposed in the plurality of pixel areas UPA includes a plurality of sub pixels SP. Each of the plurality of sub pixels SP includes a light emitting diode LED and a pixel circuit to independently emit light.

The display panel PN includes a plurality of pixels PX which are formed by a plurality of sub pixels SP, respectively. Each of the plurality of sub pixels SP includes a light emitting diode LED and a pixel circuit to independently emit light. One pixel may include one or more first sub pixels, one or more second sub pixels, and one or more third sub pixels. For example, one pixel may include two first sub pixels, two second sub pixels, and two third sub pixels. At this time, the first sub pixel is a red sub pixel, the second sub pixel is a green sub pixel, and the third sub pixel is a blue sub pixel, but it is not limited thereto.

The plurality of gate driving areas GA are areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, for example, the gate driver GD may include a plurality of transistors and/or capacitors. Here, active layers of the plurality of transistors may be formed of a semiconductor material, such as an oxide semiconductor, amorphous silicon, or polysilicon, but are not limited thereto. The active layers of the plurality of transistors may be formed of the same material or different materials from each other. Further, the active layers of the transistors of the gate driver may be formed of the same material as active layers of various transistors of the pixel circuit or formed of different materials from each other.

The plurality of top pad areas include a first top pad area TPA1 located in a first edge EG1 of the display panel PN and a second top pad area TPA2 located in a second edge EG2 of the display panel PN.

The first top pad area TPA1 and the second top pad area TPA2 are areas in which a plurality of top pads TPAD disposed on the first substrate 110 is disposed. The plurality of top pads TPAD may transmit various signals to various wiring lines extending in a column direction in the active area AA.

In the first top pad area TPA1, a plurality of first top pads TPAD1 may be disposed. The plurality of first top pads TPAD1 may include top pads TPAD to which different signals are applied. For example, the first top pad TPAD1 may include a top data pad TDP which transmits a data voltage to a top data line TDL, a top gate pad TGP which transmits a clock signal, a start signal, a gate low voltage, and a gate high voltage for driving the gate driver GD to the gate driver GD, and a top high potential power pad TVP1 which transmits a high potential power voltage to the top high potential power line TVL1.

In the second top pad area TPA2, a plurality of second top pads TPAD2 may be disposed. At this time, the plurality of second top pads TPAD2 may be different from the plurality of first top pads TPAD1. For example, the plurality of second top pads TPAD2 may include a top low potential power pad TVP2 which transmits a low potential power voltage to the plurality of top low potential power lines TVL2.

At this time, the plurality of top pads TPAD may be formed to have different sizes, respectively. For example, the plurality of top data pads TDP, which is connected to the plurality of top data lines TDL one to one, of the plurality of first top pads TPAD1 may have a smaller width and the top high potential power pad TVP1 and the top gate pad TGP may have larger widths. Further, the top low potential power pad TVP2 which is the plurality of second top pads TPAD2 may also have a larger width than that of the plurality of top data pads TDP and the top low potential power pads TVP2 may have different widths, respectively. However, widths of the top data pad TDP, the top gate pad TGP, the top high potential power pad TVP1, and the top low potential power pads TVP2 illustrated in FIG. 3 are illustrative so that the top pad TPAD may be configured in various sizes, but is not limited thereto.

A plurality of top ground pad TGNP may be disposed on the first substrate 110.

The plurality of top ground pads TGNP may be disposed in a first edge EG1 of the first substrate 110. For example, the plurality of top ground pads TGNP may be disposed in the first top pad area TPA1. Further, the plurality of top ground pads TGNP may be disposed to be adjacent to an outer peripheral area of the first substrate 110. For example, the plurality of top ground pads TGNP may be disposed to be spaced apart from each other with the plurality of first top pads TPAD1 therebetween.

The plurality of top ground pads TGNP may be respectively connected to a plurality of bottom ground pads to be described below.

In the meantime, in order to reduce the bezel of the display panel PN, an edge of the display panel PN may be cut to be removed. The plurality of pixels PX, the plurality of wiring lines, and the plurality of top pads TPAD are formed on an initial first substrate 110i and an edge portion of the initial first substrate 110i is ground to reduce the bezel area. During the grinding process, a portion of the initial first substrate 110i is removed to form a first substrate 110 with a smaller size. At this time, portions of the plurality of top pads TPAD and wiring lines disposed at the edge of the first substrate 110 may be removed. Accordingly, only a portion of the plurality of top pads TPAD may remain on the first substrate 110.

A plurality of top data lines TDL extending from the plurality of top pads TPAD in the column direction is disposed in the plurality of pixel areas UPA on the first substrate 110 of the display panel PN. The plurality of top data lines TDL may extend from the plurality of top data pads TDP of the first top pad area TPA1 toward the plurality of pixel areas UPA. The plurality of top data lines TDL extend in a column direction and may be disposed to overlap the plurality of pixel areas UPA. Therefore, the plurality of top data lines TDL may transmit the data voltage to the pixel circuit of each of the plurality of sub pixels SP.

The plurality of top high potential power lines TVL1 extending in the column direction are disposed in the plurality of pixel areas UPA on the first substrate 110 of the display panel PN. Some of the plurality of top high potential power lines TVL1 extend from the top high potential power pad TVP1 of the first top pad area TPA1 to the plurality of pixel areas UPA to transmit the high potential power voltage to the light emitting diodes LED of the plurality of sub pixels SP. The others of the plurality of top high potential power lines TVL1 may be electrically connected to the other top high potential power line TVL1 by means of a top auxiliary high potential power line TAVL1 to be described below. In FIG. 3, for the convenience of description, even though it is illustrated that one top high potential power line TVL1 and one top high potential power pad TVP1 are disposed, a plurality of top high potential power lines TVL1 and top high potential power pads TVP1 may be disposed.

The plurality of top low potential power lines TVL2 extending in the column direction are disposed in the plurality of pixel areas UPA on the first substrate 110 of the display panel PN. At least some of the plurality of top low potential power lines TVL2 extend from the top low potential power pad TVP2 of the second top pad area TPA2 to the plurality of pixel areas UPA to transmit the low potential power voltage to the pixel circuit of each of the plurality of sub pixels SP. The others of the plurality of top low potential power lines TVL2 may be electrically connected to the other top low potential power line TVL2 by means of a top auxiliary low potential power line TAVL2 to be described below.

The plurality of top scan lines TSL extending in the row direction are disposed in the plurality of pixel areas UPA on the first substrate 110 of the display panel PN. The plurality of top scan lines TSL extend in the row direction and may be disposed across the plurality of pixel areas UPA and the plurality of gate driving areas GA. The plurality of top scan lines TSL may transmit the scan signal from the gate driver GD to the pixel circuits of the plurality of sub pixels SP.

The plurality of top auxiliary high potential power lines TAVL1 extending in the row direction are disposed in the plurality of pixel areas UPA on the first substrate 110 of the display panel PN. The plurality of top auxiliary high potential power lines TAVL1 may be disposed in an area between the plurality of pixel areas UPA. The plurality of top auxiliary high potential power lines TAVL1 extending in the row direction are electrically connected to the plurality of top high potential power lines TVL1 extending in the column direction through a contact hole to form a mesh structure. Therefore, the plurality of top auxiliary high potential power lines TAVL1 and the plurality of top high potential power lines TVL1 are configured to form a mesh structure to minimize or at least reduce voltage drop and voltage deviation.

The plurality of top auxiliary low potential power lines TAVL2 extending in the row direction are disposed in the plurality of pixel areas UPA on the first substrate 110 of the display panel PN. The plurality of top auxiliary low potential power lines TAVL2 may be disposed in an area between the plurality of pixel areas UPA. The plurality of top auxiliary low potential power lines TAVL2 extending in the row direction are electrically connected to the plurality of top low potential power lines TVL2 extending in the column direction through a contact hole to form a mesh structure. Therefore, the plurality of top auxiliary low potential power lines TAVL2 and the plurality of top low potential power lines TVL2 are configured to form a mesh structure to reduce a resistance of the wiring line and minimize or at least reduce voltage deviation.

Referring to FIG. 3, the plurality of top gate driving lines TGVL extending in the row direction and the column direction are disposed in the plurality of pixel areas UPA on the first substrate 110 of the display panel PN. Some of the plurality of top gate driving lines TGVL extend from the top gate pad TGP of the first top pad area TPA1 to the gate driving area GA to transmit a signal to the gate driver GD. The others of the plurality of top gate driving lines TGVL extend in the row direction and may transmit the signal to the gate drivers GD of the plurality of gate driving areas GA. Therefore, various signals are transmitted from the top gate driving line TGVL to the gate driver GD to drive the gate driver GD.

The plurality of top gate driving lines TGVL may include wiring lines which transmit a clock signal, a start signal, a gate high voltage, and a gate low voltage to the gate driver GD. Therefore, various signals are transmitted from the top gate driving line TGVL to the gate driver GD to drive the gate driver GD.

For example, the plurality of top gate driving lines TGVL may include a plurality of gate power lines which transmit a power voltage to the gate driver GD of the gate driving area GA. The plurality of gate power lines may include a first gate power line which transmits a gate high voltage to the gate driver GD and a second gate power line which transmits a gate low voltage to the gate driver GD.

A plurality of alignment keys AK1 and AK2 are disposed in an area between the plurality of pixel areas UPA in the display panel PN. The plurality of alignment keys AK1 and AK2 are used for alignment during the manufacturing process of the display panel PN. The plurality of alignment keys AK1 and AK2 include a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes LED. For example, the first alignment key AK1 may have a cross shape, but is not limited thereto.

The second alignment key AK2 may be disposed to overlap the top high potential power line TVL1 between the plurality of pixel areas UPA. In the top high potential power line TVL1, a hole overlapping the second alignment key AK2 is formed to divide the second alignment key AK2 and the top high potential power line TVL1. The second alignment key AK2 may be used to align the display panel PN and a donor. The display panel PN and the donor are aligned using the second alignment key AK2 and the plurality of light emitting diodes LED of the donor may be transferred onto the display panel PN. For example, the second alignment key AK2 may have a circular ring shape, but is not limited thereto.

FIG. 4 is an enlarged plan view of a second substrate of a display device according to an exemplary embodiment of the present disclosure.

First, the display panel PN includes a second substrate 130. The second substrate 130 is a substrate which supports components disposed below the display device 100 and may be an insulating substrate. For example, a plurality of flexible films COF and printed circuit boards PCB which transmit signals to the plurality of sub pixels SP may be disposed below the second substrate 130.

The second substrate 130 may be formed of glass or resin. Further, the second substrate 130 may include polymer or plastic. The second substrate 130 may be formed of the same material as the first substrate 110. In some exemplary embodiments, the second substrate 130 may be formed of a plastic material having flexibility.

Referring to FIG. 4, the second substrate 130 may include a plurality of bottom pad areas, a COF pad area BPA3, and a plurality of bottom line areas.

The plurality of bottom pad areas are areas in which a plurality of bottom pads BPAD disposed below the second substrate 130 is disposed. For example, the plurality of bottom pad areas may include a first bottom pad area BPA1 located in a first edge EG1 of the display panel PN and a second bottom pad area BPA2 located in a second edge EG2 of the display panel PN. The plurality of bottom pads BPAD may transmit various signals to various wiring lines disposed in the plurality of bottom line areas.

Referring to FIG. 4, the plurality of first bottom pads BPAD1 may be disposed in the first bottom pad area BPA1. The plurality of first bottom pads BPAD1 may include a plurality of bottom pads BPAD to which different signals are applied. For example, the plurality of first bottom pads BPAD1 may include a bottom data pad BDP, a bottom gate pad BGP, and a bottom high potential power pad BVP1.

In the meantime, the plurality of bottom pads BPAD may be formed to have different sizes, respectively. For example, the plurality of first bottom pads BPAD1 may have different sizes, respectively. Specifically, the plurality of bottom data pads BDP which are connected to the plurality of bottom data link lines BDL one to one may have a smaller width and the bottom high potential power pad BVP1 and the bottom gate pad BGP may have a larger width. However, the widths of the bottom data pad BDP, the bottom gate pad BGP, and the bottom high potential power pad BVP1 illustrated in FIG. 4 are illustrative and the size of the bottom pad BPAD may vary, but is not limited thereto.

In the first bottom pad area BPA1, a plurality of bottom ground pads BGNP may be disposed on both sides of the first bottom pad BPAD1 in the first bottom pad area BPA1.

The plurality of bottom ground pads BGNP may be disposed in a first bottom pad area BPA1 of a first edge EG1 of the second substrate 130. Further, the plurality of bottom ground pads BGNP may be disposed to be adjacent to an outer peripheral area of the second substrate 130. For example, the plurality of bottom ground pads BGNP may be disposed to be spaced apart from each other with the plurality of first bottom pads BPAD1 therebetween.

The plurality of bottom ground pads BGNP may be respectively connected to the plurality of top ground pads TGNP and may be electrically connected to a bottom auxiliary low potential power line BAVL2 to be described below.

In the second bottom pad area BPA2, a plurality of second bottom pads BPAD2 may be disposed. At this time, the plurality of second bottom pads BPAD2 may be bottom pads BPAD which are different from the plurality of first bottom pads BPAD1. For example, the plurality of second bottom pads BPAD2 may include a bottom low potential power pad BVP2 which transmits a low potential power voltage to the bottom low potential power line BVL2.

In the meantime, the plurality of second bottom pads BPAD2 may have different sizes, respectively. For example, each of the plurality of second bottom pads BPAD2 may have larger width than those of the plurality of bottom data pads BDP of the plurality of first bottom pads BPAD1, but is not limited thereto. Further, the width of the bottom low potential power pad BVP2 illustrated in FIG. 4 is illustrative and the size of the bottom pad BPAD may vary, but is not limited thereto.

In the meantime, in order to reduce the bezel of the display panel PN, an edge of the display panel PN may be cut to be removed. The plurality of pixels PX, the plurality of wiring lines, and the plurality of bottom pads BPAD are formed on an initial second substrate 130i and an edge portion of the initial second substrate 130i is ground to reduce the bezel area. During the grinding process, a portion of the initial second substrate 130i is removed to form a second substrate 130 with a smaller size. At this time, portions of the plurality of bottom pads BPAD and wiring lines disposed in the edge of the second substrate 130 may be removed. Accordingly, only a portion of the plurality of bottom pads BPAD may remain on a second substrate 130.

A COF pad area BPA3 is disposed between the first bottom pad area BPA1 and the second bottom pad area BPA2. For example, the COF pad area BPA3 may be disposed to be adjacent to the first bottom pad area BPA1 between the first bottom pad area BPA1 and the second bottom pad area BPA2, but is not limited thereto.

A plurality of COF pads BPAD3 are disposed in the COF pad area BPA3.

The plurality of COF pads BPAD3 may be connected to a plurality of bottom lines disposed in a plurality of bottom line areas and may electrically connect the plurality of bottom lines and the plurality of flexible films COF and printed circuit boards PCB.

For example, the plurality of bottom data link lines BDL may be connected to the plurality of COF pads BPAD3 and the plurality of COF pads BPAD3 may be electrically connected to the plurality of flexible films COF. Accordingly, the plurality of COF pads BPAD3 may electrically connect the plurality of flexible films COF and the plurality of bottom data link lines BDL.

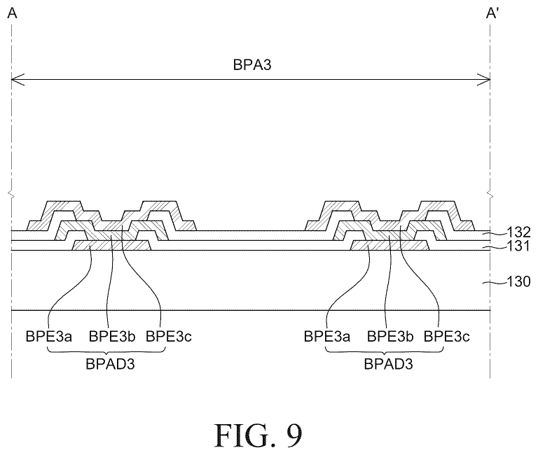

The plurality of COF pads BPAD3 will be described in detail with reference to FIG. 9.

In the meantime, the plurality of flexible films COF and printed circuit boards PCB may be disposed in the COF pad area BPA3.

The plurality of flexible films COF may be electrically connected to the plurality of COF pads BPAD3. The flexible film COF is a film in which various components are disposed on a base film having a ductility to supply a signal to the sub pixel SP and a driving component and may be electrically connected to the display panel PN.

A driving IC such as a gate driver IC or a data driver IC may be disposed on the plurality of flexible films COF. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the plurality of flexible films COF by a chip on film technique, but is not limited thereto.

The printed circuit board PCB is electrically connected to the plurality of flexible films COF. The printed circuit board PCB is a component which supplies signals to the driving IC. On the printed circuit board PCB, various components for supplying various signals to the driving IC may be disposed.

In the meantime, even though in FIG. 4, it is illustrated that three flexible films COF and one printed circuit board PCB are provided, the number of the plurality of flexible films COF and printed circuit boards PCB may vary depending on a design, but is not limited thereto.

The plurality of bottom line areas are areas in which a plurality of wiring lines connected to the plurality of bottom pads BPAD is disposed. The plurality of bottom line areas may include a first bottom line area BLA1 and a second bottom line area BLA2.

Referring to FIG. 4, the first bottom line area BLA1 and the second bottom line area BLA2 are disposed between the first bottom pad area BPA1 and the second bottom pad area BPA2. The first bottom line area BLA1 and the second bottom line area BLA2 may be disposed to be spaced apart from each other with the COF pad area BPA3 therebetween. For example, the first bottom line area BLA1 may be disposed between the first bottom pad area BPA1 and the COF pad area BPA3 and the second bottom line area BLA2 may be disposed between the second bottom pad area BPA2 and the COF pad area BPA3. Therefore, the first bottom pad area BPA1, the first bottom line area BLA1, the COF pad area BPA3, the second bottom line area BLA2, and the second bottom pad area BPA2 may be sequentially disposed from the first edge EG1 to the second edge EG2 of the display panel PN.

In the first bottom line area BLA1, the bottom data link line BDL, the bottom gate link line, the bottom high potential power line BVL1, the bottom auxiliary high potential power line BAVL1, the bottom auxiliary low potential power line BAVL2, and the plurality of bottom ground lines BGNL may be disposed.

For example, a plurality of bottom data link lines BDL which extend from the bottom data pad BDP in the column direction are disposed in the first bottom line area BLA1 of the rear surface of the second substrate 130. The plurality of bottom data link lines BDL extend toward the COF pad area BPA3 to be connected to the plurality of flexible films COF and the printed circuit board PCB. Further, the plurality of bottom data link lines BDL may be disposed so as to overlap the bottom high potential power line BVL1 and the plurality of bottom auxiliary low potential power lines BAVL2.

A plurality of bottom gate link lines which extend from the bottom gate pad BGP in the column direction are disposed in the first bottom line area BLA1 of the rear surface of the second substrate 130. The plurality of bottom gate link lines extend toward the COF pad area BPA3 to be connected to the plurality of COF pads BPAD3.

A plurality of bottom high potential power link lines which extend from the plurality of bottom high potential power pads BVP1 in the column direction are disposed in the first bottom line area BLA1 of the rear surface of the second substrate 130.

Each of the plurality of bottom high potential power link lines extends in the column direction to be connected to the bottom high potential power line BVL1.

The bottom high potential power line BVL1 may have a long axis in the row direction. For example, a width of the bottom high potential power line BVL1 may correspond to a width of the first bottom pad area BPA1. Therefore, the bottom high potential power line BVL1 may be in contact with each of the plurality of bottom high potential power link lines extending in the column direction.

A plurality of bottom auxiliary high potential power lines BAVL1 may be disposed in the first bottom line area BLA1. The plurality of bottom auxiliary high potential power lines BAVL1 may be disposed to overlap the bottom high potential power line BVL1.

In the meantime, the more adjacent to the first bottom pad are BPA1, the smaller the width of each of the plurality of bottom auxiliary high potential power lines BAVL1. For example, a planar shape of each of the plurality of bottom auxiliary high potential power lines BAVL1 may be a triangle.

A plurality of bottom auxiliary low potential power lines BAVL2 may be disposed in the first bottom line area BLA1. The plurality of bottom auxiliary low potential power lines BAVL2 may be disposed to overlap the bottom high potential power line BVL1.

Each of the plurality of the bottom auxiliary high potential power lines BAVL1 and each of the plurality of bottom auxiliary low potential power lines BAVL2 may be alternately disposed along the row direction.

In the meantime, the more adjacent to the first bottom pad area BPA1, the larger the width of each of the plurality of bottom auxiliary low potential power lines BAVL2. For example, a planar shape of each of the plurality of bottom auxiliary low potential power lines BAVL2 may be a trapezoid.

In the meantime, the plurality of bottom auxiliary low potential power lines BAVL2 may be connected to the bottom low potential power line BVL2. For example, each of the plurality of bottom auxiliary low potential power lines BAVL2 may extend to the second bottom line area BLA2 in an area between the plurality of COF pads BPAD3. Therefore, each of the plurality of bottom auxiliary low potential power lines BAVL2 may be connected to the bottom low potential power line BVL2 disposed in the second bottom line area BLA2.

Further, the plurality of bottom auxiliary low potential power lines BAVL2 may be connected to the plurality of bottom ground lines BGNL. For example, a bottom auxiliary low potential power line BAVL2 disposed in an outer peripheral area of the second substrate 130, among the plurality of bottom auxiliary low potential power lines BAVL2, may be connected to the plurality of bottom ground lines BGNL.

The plurality of bottom ground lines BGNL is disposed in the first bottom line area BLA1 of the rear surface of the second substrate 130. The plurality of bottom ground lines BGNL may be disposed to be spaced apart from each other with the bottom data link line BDL, the bottom gate link line, and the bottom high potential power line BVL1 therebetween.

The plurality of bottom ground lines BGNL extend to the first edge EG1 of the second substrate 130 to be connected to a plurality of bottom ground pads BGNP. Further, the plurality of bottom ground lines BGNL extend in the column direction to be in contact with the plurality of bottom auxiliary low potential power lines BAVL2.

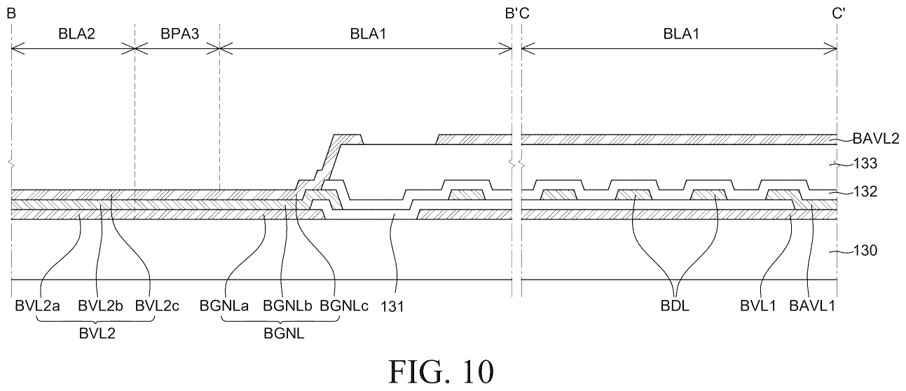

The plurality of bottom auxiliary high potential power lines BAVL1, the plurality of bottom data link lines BDL, the plurality of bottom auxiliary low potential power lines BAVL2, and the plurality of bottom ground lines BGNL will be described in detail below with reference to FIG. 10.

A plurality of bottom low potential power link lines which extend from the plurality of second bottom pads BPAD2 in the column direction are disposed in the second bottom line area BLA2 of the rear surface of the second substrate 130.

Each of the plurality of bottom low potential power link lines extends in the column direction to be connected to the bottom low potential power line BVL2.

The bottom low potential power line BVL2 may have a long axis in the row direction. For example, a width of the bottom low potential power line BVL2 may correspond to a width of the second bottom pad area BPA2. Therefore, the bottom low potential power line BVL2 may be in contact with each of the plurality of bottom low potential power link lines extending in the column direction.

The bottom low potential power line BVL2 may be in contact with the plurality of bottom auxiliary low potential power lines BAVL2 extending from the first bottom line area BLA1.

In the meantime, the bottom data link line BDL, the bottom gate link line, the bottom high potential power link line disposed in the first bottom line area BLA1 of the second substrate 130 extend to the plurality of first bottom pads BPAD1, respectively, and may be connected to the plurality of first top pads TPAD1 disposed on the first substrate 110 through a side line SRL to be described below.

Further, the bottom low potential power link lines disposed in the second bottom line area BLA2 of the second substrate 130 extend to the plurality of second bottom pads BPAD2, respectively, and may be connected to the plurality of second top pads TPAD2 disposed on the first substrate 110 through a side line SRL to be described below.

In the meantime, the plurality of bottom ground lines BGNL disposed in the first bottom line area BLA1 of the second substrate 130 extend to the first bottom pad area BPA1 to be connected to the plurality of bottom ground pads BGNP. Further, the plurality of bottom ground pads BGNP may be connected to the plurality of top ground pads TGNP disposed on the first substrate 110 through a side ground line to be described below.

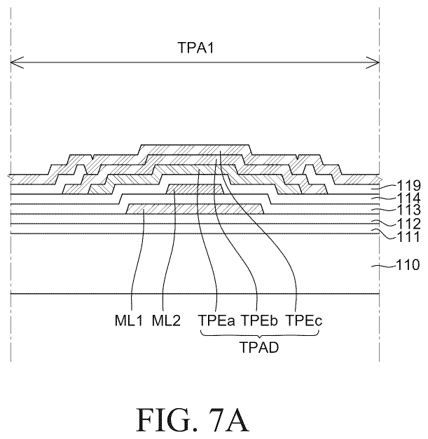

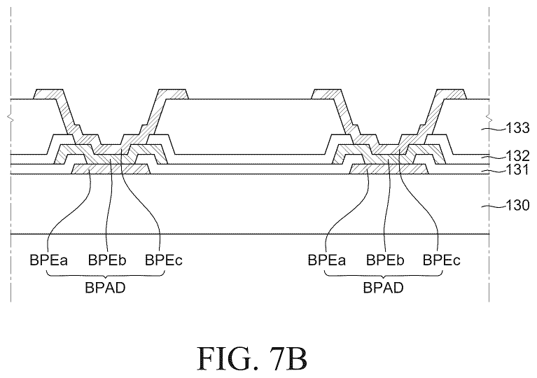

The side line SRL and the side ground line will be described in detail below with reference to FIG. 7.

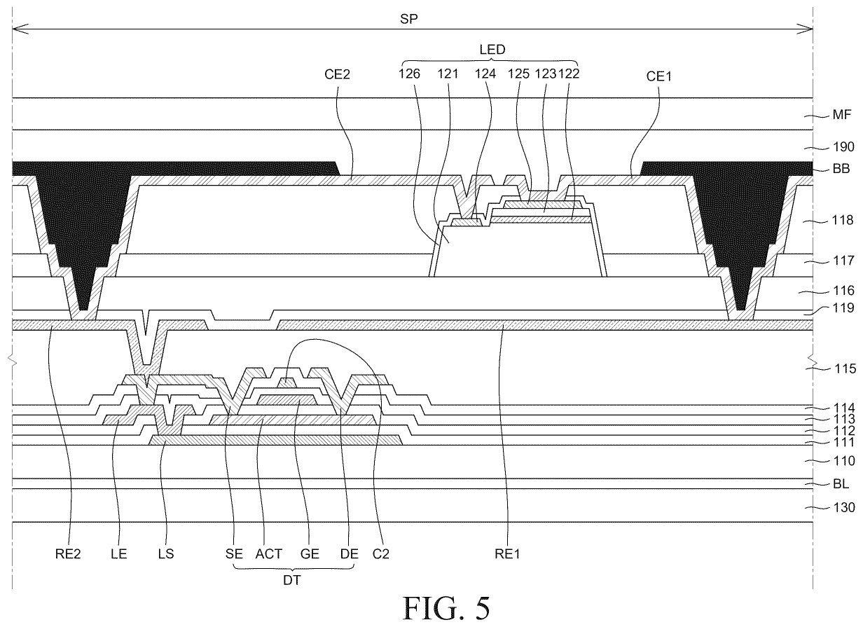

Hereinafter, the plurality of sub pixels SP of the pixel area UPA will be described in more detail with reference to FIG. 5.

FIG. 5 is a cross-sectional view of a sub pixel of a display device according to an exemplary embodiment of the present disclosure. In each of the plurality of sub pixels SP of the display panel PN of the display device 100 according to the exemplary embodiment of the present disclosure, a first substrate 110, a second substrate 130, a bonding layer BL, a buffer layer 111, a gate insulating layer 112, a first interlayer insulating layer 113, a second interlayer insulating layer 114, a first planarization layer 115, an adhesive layer 116, a second planarization layer 117, a third planarization layer 118, a passivation layer 119, a driving transistor DT, a light emitting diode LED, a plurality of reflective electrodes RE1 and RE2, a plurality of connection electrodes CE1 and CE2, a light shielding layer LS, and an auxiliary electrode LE are disposed.

First, the first substrate 110 is a component for supporting various components included in the display device 100 and may be formed of an insulating material. For example, the first substrate 110 may be formed of glass or resin. Further, the first substrate 110 may be configured to include polymer or plastics or may be formed of a material having flexibility.

The light shielding layer LS is disposed in each of the plurality of sub pixels SP on the first substrate 110. The light shielding layer LS blocks light incident onto an active layer ACT of the driving transistor DT to be described below, below the first substrate 110. Light which is incident onto the active layer ACT of the driving transistor DT is blocked by the light shielding layer LS to minimize a leakage current. For example, the light shielding layer LS may be formed of molybdenum (Mo), but is not limited thereto.

The buffer layer 111 is disposed on the first substrate 110 and the light shielding layer LS. The buffer layer 111 may reduce permeation of moisture or impurities through the first substrate 110. The buffer layer 111 may be configured by a single layer or a double layer of silicon oxide (SiOx) or silicon nitride (SiNx), but is not limited thereto. However, the buffer layer 111 may be omitted depending on a type of the first substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 is disposed on the gate electrode GE. In the first interlayer insulating layer 113, a contact hole through which the source electrode SE and the drain electrode DE are connected to the active layer ACT, respectively, is formed. The first interlayer insulating layer 113 is an insulating layer which protects components below the first interlayer insulating layer 113 and may be configured by a single layer or a double layer of silicon oxide (SiOx) or silicon nitride (SiNx), but is not limited thereto.

The capacitor electrode C2 is disposed on the first interlayer insulating layer 113. The capacitor electrode C2 may be disposed so as to overlap the gate electrode GE with the first interlayer insulating layer 113 therebetween.

The second interlayer insulating layer 114 is disposed on the capacitor electrode C2. In the second interlayer insulating layer 114, a contact hole through which the source electrode SE and the drain electrode DE are connected to the active layer ACT, respectively, is formed. The second interlayer insulating layer 114 is an insulating layer which protects components below the second interlayer insulating layer 114 and may be configured by a single layer or a double layer of silicon oxide (SiOx) or silicon nitride (SiNx), but is not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

In the meantime, in the present specification, it is described that the first interlayer insulating layer 113 and the second interlayer insulating layer 114, that is, a plurality of insulating layers is disposed between the gate electrode GE, and the source electrode SE and the drain electrode DE. However, only one insulating layer may be disposed between the gate electrode GE, and the source electrode SE and the drain electrode DE, but is not limited thereto.

As illustrated in the drawings, when a plurality of insulating layers, such as the first interlayer insulating layer 113 and the second interlayer insulating layer 114, is disposed between the gate electrode GE, and the source electrode SE and the drain electrode DE, an electrode may be further formed between the first interlayer insulating layer 113 and the second interlayer insulating layer 114. The additionally formed electrode may form a capacitor with the other configuration disposed below first interlayer insulating layer 113 or above the second interlayer insulating layer 114.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE and the drain electrode DE through the auxiliary electrode LE so as not to operate as a floating gate. Therefore, fluctuation of a threshold voltage of the driving transistor DT caused by the floated light shielding layer LS may be minimized. Even though in the drawing, the light shielding layer LS is connected to the source electrode SE, the light shielding layer LS may also be connected to the drain electrode DE, but is not limited thereto.

The first planarization layer 115 is disposed on the driving transistor DT. The first planarization layer 115 may planarize an upper portion of the first substrate 110 on which the driving transistor DT is disposed. The first planarization layer 115 may be configured by a single layer or a double layer, and for example, may be formed of photoresist or an acrylic organic material, but is not limited thereto.

A plurality of reflective electrodes RE1 and RE2 which is spaced apart from each other is disposed on the first planarization layer 115. The plurality of reflective electrodes RE1 and RE2 electrically may connect the light emitting diode LED to the power line and the driving transistor DT and may serve as a reflector which reflects light emitted from the light emitting diode LED to the upper portion of the light emitting diode LED. The plurality of reflective electrodes RE1 and RE2 is formed of a conductive material having the excellent reflecting property to reflect light emitted from the light emitting diode LED toward the upper portion of the light emitting diode LED.

For example, the plurality of reflective electrodes RE1 and RE2 may be configured by a conductive material such as copper (Cu), aluminum (Al), molybdenum (Mo), nickel (Ni), titanium (Ti), chrome (Cr), or an alloy thereof, but is not limited thereto.

The plurality of reflective electrodes RE1 and RE2 includes a first reflective electrode RE1 and a second reflective electrode RE2. The second reflective electrode RE2 may electrically connect the driving transistor DT and the light emitting diode LED. The second reflective electrode RE2 may be connected to the source electrode SE or the drain electrode DE of the driving transistor DT through a contact hole formed in the first planarization layer 115. The second reflective electrode RE2 may be electrically connected to the first electrode 124 of the light emitting diode LED through a second connection electrode CE2 to be described below.

The first reflective electrode RE1 may electrically connect the power line and the light emitting diode LED. The first reflective electrode RE1 may be connected to the power line and may be electrically connected to the second electrode 125 of the light emitting electrode LED through a first connection electrode CE1 to be described below.

The passivation layer 119 is disposed on the plurality of reflective electrodes RE1 and RE2. In the passivation layer 119, a contact hole through which the plurality of reflective electrodes RE1 and RE2 is coupled to the first connection electrode CE1 and the second connection electrode CE2, respectively, is disposed. The passivation layer 119 is an insulating layer which protects components below the passivation layer 119 and may be configured by a single layer or a double layer of silicon oxide (SiOx) or silicon nitride (SiNx), but is not limited thereto.

The adhesive layer 116 is disposed on the passivation layer 119. The adhesive layer 116 is coated on the front surface of the first substrate 110 to fix the light emitting diode LED disposed on the adhesive layer 116. For example, the adhesive layer 116 may be selected from any one of adhesive polymer, epoxy resin, UV resin, polyimide, acrylate, urethane, and polydimethylsiloxane (PDMS), but is not limited thereto.

The plurality of light emitting diodes LED is disposed in each of the plurality of sub pixels SP on the adhesive layer 116. The plurality of light emitting diodes LED is an element which emits light by a current and may include a light emitting diode LED which emits red light, green light, and blue light and may implement various colored light including white by a combination thereof. For example, the plurality of light emitting diodes LED may be a light emitting diode (LED) or a micro-LED, but is not limited thereto.

The plurality of light emitting diodes LED may include a first light emitting diode, a second light emitting diode, and a third light emitting diode. In the first sub pixel, the first light emitting diode may be disposed, in the second sub pixel, the second light emitting diode may be disposed, and in the third sub pixel, the third light emitting diode may be disposed. For example, the first light emitting diode may be a red light emitting diode, the second light emitting diode may be a green light emitting diode, and the third light emitting diode may be a blue light emitting diode.

Each of the plurality of light emitting diodes LED includes a first semiconductor layer 121, an emission layer 122, a second semiconductor layer 123, a first electrode 124, a second electrode 125, and an encapsulation layer 126.

The first semiconductor layer 121 is disposed on the adhesive layer 116 and the second semiconductor layer 123 is disposed on the first semiconductor layer 121. The first semiconductor layer 121 and the second semiconductor layer 123 may be layers formed by doping n-type and p-type impurities into a specific material. For example, the first semiconductor layer 121 and the second semiconductor layer 123 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium, and tin (Sn), but is not limited thereto.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 is an electrode which electrically connects the driving transistor DT and the first semiconductor layer 121. The first electrode 124 may be disposed on a top surface of the first semiconductor layer 121 which is exposed from the emission layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 may be disposed on the top surface of the second semiconductor layer 123. The second electrode 125 is an electrode which electrically connects the power line and the second semiconductor layer 123. The second electrode 125 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 126 which encloses the first semiconductor layer 121, the emission layer 122, the second semiconductor layer 123, the first electrode 124, and the second electrode 125 is disposed. The encapsulation layer 126 is formed of an insulating material to protect the first semiconductor layer 121, the emission layer 122, and the second semiconductor layer 123. In the encapsulation layer 126, a contact hole which exposes the first electrode 124 and the second electrode 125 is formed to electrically connect a first connection electrode CE1 and a second connection layer CE2 to the first electrode 124 and the second electrode 125.

The second planarization layer 117 and the third planarization layer 118 are disposed on the adhesive layer 116. The second planarization layer 117 overlaps a part of side surfaces of the plurality of light emitting diodes LED to fix and protect the plurality of light emitting diodes LED. Specifically, even though in FIG. 5, it is illustrated that the encapsulation layer 126 encloses all the side surfaces of the first semiconductor layer 121, a portion of the side surface of the first semiconductor layer 121 may be exposed from the encapsulation layer 126. The light emitting diode LED manufactured on the wafer is separated from the wafer to be transferred onto the display panel PN. However, during the process of separating the light emitting diode LED from the wafer, a portion of the encapsulation layer 126 may be torn. For example, a portion of the encapsulation layer 126 which is adjacent to a lower edge of the first semiconductor layer 121 of the light emitting diode LED is torn during the process of separating the light emitting diode LED from the wafer. Accordingly, a portion of a lower side surface of the first semiconductor layer 121 may be exposed to the outside. However, even though the lower portion of the light emitting diode LED is exposed from the encapsulation layer 126, the first connection electrode CE1 and the second connection electrode CE2 are formed after forming the second planarization layer 117 which covers the side surface of the first semiconductor layer 121. Accordingly, a short defect may be minimized.

Further, the third planarization layer 118 is formed to cover upper portions of the second planarization layer 117 and the light emitting diode LED and a contact hole which exposes the first electrode 124 and the second electrode 125 of the light emitting diode LED may be formed. The first electrode 124 and the second electrode 125 of the light emitting diode LED are exposed from the third planarization layer 118 and the third planarization layer 118 is partially disposed in an area between the first electrode 124 and the second electrode 125 to minimize a short defect.

The second planarization layer 117 and the third planarization layer 118 may be configured by a single layer or a double layer, and for example, may be formed of photoresist or an acrylic organic material, but is not limited thereto. Even though in the specification, it is described that the second planarization layer 117 and the third planarization layer 118 are disposed, the planarization layer may be formed by a single layer, but is not limited thereto.

A plurality of connection electrodes CE1 and CE2 are disposed on the third planarization layer 118. The plurality of connection electrodes CE1 and CE2 include a first connection electrode CE1 and a second connection electrode CE2.

The second connection electrode CE2 is an electrode which is disposed in each of the plurality of sub pixels SP to electrically connect the light emitting diode LED and the driving transistor DT. The second connection electrode CE2 may be connected to the second reflective electrode RE2 through the contact holes formed in the third planarization layer 118, the second planarization layer 117, and the adhesive layer 116. Accordingly, the second connection electrode CE2 may be electrically connected to any one of the source electrode SE and the drain electrode DE of the driving transistor DT through the second reflective electrode RE2. The second connection electrode CE2 may be connected to the first electrodes 124 of the plurality of light emitting diodes LED through a contact hole formed in the third planarization layer 118. Accordingly, the second connection electrode CE2 may electrically connect the driving transistor DT to the first electrode 124 of the plurality of light emitting diodes LED.

The first connection electrode CE1 is an electrode for electrically connecting the light emitting diode LED and the power line. The first connection electrode CE1 may be connected to the first reflective electrode RE1 through the contact holes formed in the third planarization layer 118, the second planarization layer 117, and the adhesive layer 116. Further, the first connection electrode CE1 may be electrically connected to the power line through the first reflective electrode RE1. The first connection electrode CE1 may be connected to the second electrodes 125 of the plurality of light emitting diodes LED through a contact hole formed in the third planarization layer 118. Accordingly, the first connection electrode CE1 may electrically connect the power line to the second electrode 125 of the plurality of light emitting diodes LED.

The bank BB is disposed on the first connection electrode CE1 and the second connection electrode CE2. The bank BB may be disposed to be spaced apart from the light emitting diode LED with a predetermined interval.

The bank BB may be formed of an opaque material to reduce color mixture between the plurality of sub pixels SP and for example, may be formed of black resin, but is not limited thereto.

The protection layer 190 is disposed on the first connection electrode CE1, the second connection electrode CE2, and the bank BB. The protection layer 190 is a layer for protecting a configuration below the protection layer 190 and for example, may cover at least a portion of the light emitting diode LED. The protection layer 190 may be configured by a single layer or a double layer of translucent epoxy, silicon oxide (SiOx) or silicon nitride (SiNx), but is not limited thereto.

In the meantime, the second connection electrode CE2 which connects the driving transistor DT and the light emitting diode LED which are disposed in each of the plurality of sub pixels SP may be individually disposed in each of the plurality of sub pixels SP.

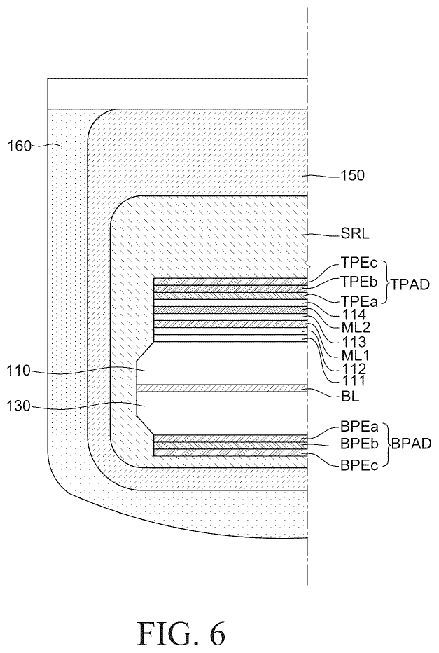

Hereinafter, a plurality of top pads TPAD and a plurality of bottom pads BPAD will be described in detail with reference to FIGS. 6 to 7B together.

FIG. 6 is a cross-sectional view of a pad area of a display device according to an exemplary embodiment of the present disclosure. FIG. 7A is a cross-sectional view of a top pad of a display device according to an exemplary embodiment of the present disclosure. FIG. 7B is a cross-sectional view of a bottom pad of a display device according to an exemplary embodiment of the present disclosure. In FIG. 7B, it is illustrated that positions of the second substrate 130 and components below the second substrate 130 are inverted so as to dispose the second substrate 130 is disposed at the bottom, for the convenience of illustration.

Referring to FIGS. 6 and 7A, each of a plurality of top pads TPAD may be formed by a plurality of conductive layers. For example, each of the plurality of top pads TPAD may include a first top pad electrode TPEa, a second top pad electrode TPEb, and a third top pad electrode TPEc. That is, each of the plurality of first top pads TPAD1 and the plurality of second top pads TPAD2 may include a first top pad electrode TPEa, a second top pad electrode TPEb, and a third top pad electrode TPEc.

First, the first top pad electrode TPEa may be disposed a same layer as the driving transistor DT. For example, the first top pad electrode TPEa is disposed on the second interlayer insulating layer 114. The first top pad electrode TPEa may be formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The second top pad electrode TPEb is disposed on the first top pad electrode TPEa. The second top pad electrode TPEb may be disposed on a same layer as the plurality of reflective electrodes RE1 and RE2 and formed of the same conductive material as the plurality of reflective electrodes RE1 and RE2. The second top pad electrode TPEb may be configured by a conductive material such as copper (Cu), aluminum (Al), molybdenum (Mo), nickel (Ni), titanium (Ti), chrome (Cr), or an alloy thereof, but is not limited thereto.

The third top pad electrode TPEc is disposed on the second top pad electrode TPEb. The third top pad electrode TPEc may be disposed on a same layer as the first connection electrode CE1 and the second connection electrode CE2 and formed of the same conductive material as the first connection electrode CE1 and the second connection electrode CE2, and for example, a transparent conductive material, such as indium tin oxide (ITO) or indium zinc oxide (IZO), but is not limited thereto.

At this time, even though it is not illustrated in the drawings, a portion of the plurality of top pad electrodes of the top pad TPAD is electrically connected to a plurality of wiring lines on the first substrate 110 to supply various signals to a plurality of wiring lines and a plurality of sub pixels SP. For example, the first top pad electrodes TPEa and/or the second top pad electrodes TPEb of the top pad TPAD is connected to the top data line TDL, the top high potential power line TVL1, and the top low potential power line TVL2, etc. disposed in the active area AA to transmit signals thereto.

A first metal layer ML1, a second metal layer ML2, and a plurality of insulating layers may be disposed together below the top pad TPAD. The first metal layer ML1, the second metal layer ML2, and the plurality of insulating layers are disposed below the top pad TPAD to adjust a step of the top pad TPAD. For example, the buffer layer 111, the gate insulating layer 112, the first metal layer ML1, the first interlayer insulating layer 113, and the second metal layer ML2 may be sequentially disposed between the top pad TPAD and the first substrate 110. The first metal layer ML1 may be formed of the same conductive material as the gate electrode GE and the second metal layer ML2 may be formed of the same conductive material as a capacitor electrode C2. However, the plurality of insulating layers, the first metal layer ML1, and the second metal layer ML2 below the top pad TPAD may be omitted depending on a design and are not limited thereto.

Referring to FIG. 5 together, a second substrate 130 is disposed below the first substrate 110. The second substrate 130 is a substrate which supports components disposed below the display device 100 and may be an insulating substrate. For example, the second substrate 130 may be formed of glass or resin. Further, the second substrate 130 may include polymer or plastic. The second substrate 130 may be formed of the same material as the first substrate 110. In some exemplary embodiments, the second substrate 130 may be formed of a plastic material having flexibility.

Referring to FIG. 5 together, a bonding layer BL is disposed between the first substrate 110 and the second substrate 130. The bonding layer BL may be formed of a material which is cured by various curing methods to bond the first substrate 110 and the second substrate 130. The bonding layer BL may be disposed only in a partial area between the first substrate 110 and the second substrate 130 or may be disposed in the entire area therebetween.

A plurality of bottom pads BPAD are disposed on the rear surface of the second substrate 130. The plurality of bottom pads BPAD are electrodes which transmit a signal from a driving component disposed on the rear surface of the second substrate 130 to a plurality of side lines SRL, and a plurality of top pads TPAD and a plurality of wiring lines on the first substrate 110. The plurality of bottom pads BPAD are disposed in an end portion of the second substrate 130 in the non-active area NA to be electrically connected to the side line SRL which covers the end portion of the second substrate 130.

At this time, the plurality of bottom pads BPAD may also be disposed so as to correspond to the plurality of bottom pad areas. Each of the plurality of top pads TPAD may be disposed so as to correspond to each of the plurality of bottom pads BPAD and then the top pads TPAD and the bottom pads BPAD which overlap each other may be electrically connected through the side line SRL.

Each of the plurality of bottom pads BPAD includes a plurality of pad electrodes. For example, each of the plurality of bottom pads BPAD includes a first bottom pad electrode BPEa, a second bottom pad electrode BPEb, and a third bottom pad electrode BPEc. That is, each of the plurality of first bottom pads BPAD1 and the plurality of second bottom pads BPAD2 includes a first bottom pad electrode BPEa, a second bottom pad electrode BPEb, and a third bottom pad electrode BPEc.

In FIG. 7B, it is illustrated that the bottom pad BPAD is disposed on the second substrate 130 for the convenience of illustration and the first bottom pad electrode BPEa, the second bottom pad electrode BPEb, and the third bottom pad electrode BPEc are sequentially disposed above the second substrate 130.

However, the second substrate 130 illustrated in FIG. 7B is disposed upside down to be bonded to the first substrate 110. Therefore, in the bonded state of the second substrate 130 and the first substrate 110, as illustrated in FIG. 6, the plurality of bottom pads BPAD may be disposed below the second substrate 130. Further, the first bottom pad electrode BPEa, the second bottom pad electrode BPEb, and the third bottom pad electrode BPEc may be sequentially disposed below the second substrate 130.

Hereinafter, it is described based on a state in which the second substrate 130 is bonded to the first substrate 110 and it is described that the first bottom pad electrode BPEa, the second bottom pad electrode BPEb, and the third bottom pad electrode BPEc are sequentially disposed below the second substrate 130.

First, the first bottom pad electrode BPEa is disposed below the second substrate 130. The first bottom pad electrode BPEa may be configured by a conductive material such as copper (Cu), aluminum (Al), molybdenum (Mo), nickel (Ni), titanium (Ti), chrome (Cr), or an alloy thereof, but is not limited thereto.

The first insulating layer 131 is disposed below the first bottom pad electrode BPEa. Referring to FIG. 7B, the first insulating layer 131 may cover a side surface of the first bottom pad electrode BPEa. In the meantime, the first insulating layer 131 may include an opening which exposes a portion of one surface of the first bottom pad electrode BPEa.

The first insulating layer 131 may be an inorganic insulating layer. For example, the first insulating layer 131 may be configured by a single layer or a double layer of silicon oxide (SiOx) or silicon nitride (SiNx), but is not limited thereto.

The second bottom pad electrode BPEb is disposed below the first insulating layer 131. Referring to FIG. 7B, the second bottom pad electrode BPEb may be in contact with one surface of the first bottom pad electrode BPEa exposed by the opening of the first insulating layer 131.

The second bottom pad electrode BPEb may be configured by a conductive material such as copper (Cu), aluminum (Al), molybdenum (Mo), nickel (Ni), titanium (Ti), chrome (Cr), or an alloy thereof, but is not limited thereto.

The second insulating layer 132 is disposed below the second bottom pad electrode BPEb. The second insulating layer 132 may cover the side surface of the second bottom pad electrode BPEb. Further, the second insulating layer 132 may include an opening which exposes a portion of one surface of the second bottom pad electrode BPEb.

The second insulating layer 132 may be an inorganic insulating layer. For example, the second insulating layer 132 may be configured by a single layer or a double layer of silicon oxide (SiOx) or silicon nitride (SiNx), but is not limited thereto.

A third insulating layer 133 is disposed below the second insulating layer 132. The third insulating layer 133 may include an opening which exposes a portion of the second insulating layer 132. For example, the opening of the third insulating layer 133 is disposed so as to overlap an opening of the second insulating layer 132 which exposes a portion of one surface of the second bottom pad electrode BPEb to expose a portion of one surface of the second bottom pad electrode BPEb.

The third insulating layer 133 may be an organic insulating layer. For example, the third insulating layer 133 may be formed of photoresist or an acrylic organic material, but is not limited thereto.

The third insulating layer 133 may have a thickness larger than those of the first insulating layer 131 and the second insulating layer 132. Therefore, the third insulating layer 133 may form a higher step together with one surface of the second bottom pad electrode BPEb. Therefore, when the plurality of bottom pads BPAD are in contact with a plurality of side lines SRL, a migration phenomenon that metal ions are transferred to the plurality of top pads TPAD, the plurality of bottom pads BPAD, and the plurality of side lines SRL in a high current or high humidity environment may be suppressed.

The third bottom pad electrode BPEc is disposed below the third insulating layer 133. Referring to FIG. 7B, the third bottom pad electrode BPEc may be in contact with one surface of the second bottom pad electrode BPEb exposed by the opening of the second insulating layer 132 and the opening of the third insulating layer 133.

The third bottom pad electrode BPEc may be formed of a material which is hardly corroded even when in contact with air or moisture in order to suppress the corrosion of the second bottom pad electrode BPEb. For example, the third bottom pad electrode BPEc may be formed of a conductive material, for example, a transparent conductive material, such as indium tin oxide (ITO) or indium zinc oxide (IZO), but is not limited thereto.

In the meantime, in order to increase a contact area with the plurality of side lines SRL, the third bottom pad electrode BPEc extends from one surface of the second bottom pad electrode BPEb to cover the side surface and a portion of one surface of the third insulating layer 133, but is not limited thereto.

In the meantime, a driving component including a plurality of flexible films COF and a printed circuit board PCB may be disposed on a rear surface of the second substrate 130. The first bottom pad electrode BPEa and/or the second bottom pad electrode BPEb of the plurality of bottom pads BPAD extend toward the plurality of flexible films COF disposed on the rear surface of the second substrate 130 to be electrically connected to the plurality of flexible films COF. The plurality of flexible films COF may supply various signals to the plurality of side lines SRL, the plurality of top pads TPAD, the plurality of wiring lines, and the plurality of sub pixels SP through the plurality of bottom pads BPAD. Therefore, the signal from the driving component may be transmitted to the signal line and the plurality of sub pixels SP on the front surface of the first substrate 110 through the plurality of bottom pads BPAD of the second substrate 130, the side line SRL, and the plurality of top pads TPAD of the first substrate 110.

Referring to FIG. 6 again, the plurality of side lines SRL are disposed on the side surfaces of the first substrate 110 and the second substrate 130. The plurality of side lines SRL may electrically connect the plurality of top pads TPAD formed on the top surface of the first substrate 110 and the plurality of bottom pads BPAD formed on the rear surface of the second substrate 130. The plurality of side lines SRL may be disposed so as to enclose the side surface of the display device 100. Each of the plurality of side lines SRL may cover the plurality of top pads TPAD at an end portion of the first substrate 110, a side surface of the first substrate 110, a side surface of the second substrate 130, and the plurality of bottom pads BPAD at an end portion of the second substrate 130. For example, the plurality of side lines SRL may be formed by a pad printing method using a conductive ink including silver (Ag), copper (Cu), molybdenum (Mo), or chrome (Cr).

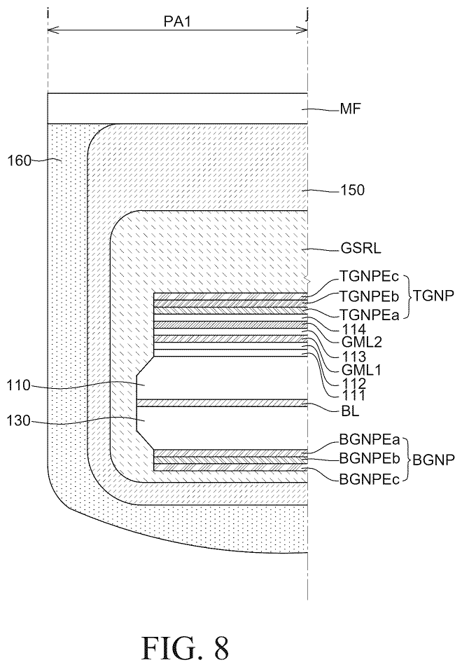

Hereinafter, a plurality of top ground pads and a plurality of bottom ground pads will be described in detail with reference to FIG. 8 together.

FIG. 8 is a cross-sectional view of a ground pad of a display device according to an exemplary embodiment of the present disclosure.

Referring to FIG. 8, the plurality of bottom ground pads BGNP and the plurality of top ground pads TGNP may be connected through a plurality of side ground lines GSRL. In the meantime, the plurality of top ground pads, the plurality of bottom ground pads, and the plurality of side ground lines GSRL are formed with the same structure as the plurality of top pads TPAD, the plurality of bottom pads BPAD, and the side line SRL, respectively.

For example, referring to FIG. 8, each of the plurality of top ground pads TGNP may include a first top ground pad electrode TGNPEa, a second top ground pad electrode TGNPEb, and a third top ground pad electrode TGNPEc. The first top ground pad electrode TGNPEa is formed of the same material as the first top pad electrode TPEa on the same layer as the first top pad electrode TPEa. The second top ground pad electrode TGNPEb is formed of the same material as the second top pad electrode TEPb on the same layer as the second top pad electrode TEPb. The third top ground pad electrode TGNPEc is formed of the same material as the third top pad electrode TPEc on the same layer as the third top pad electrode TPEc.

Even though it is not illustrated in the drawings, the plurality of top ground pads TGNP is electrically connected to a plurality of wiring lines on the first substrate 110 to supply a ground signal to the plurality of wiring lines and the plurality of sub pixels SP.

A first conductive layer GML1 formed of the same material as the first metal layer ML1 on the same layer as the first metal layer ML1 and a second conductive layer GML2 formed of the same material as the second metal layer ML2 on the same layer as the second metal layer ML2, and the plurality of insulating layers may be disposed together below the plurality of top ground pads TGNP.

A plurality of bottom ground pads BGNP are disposed on the rear surface of the second substrate 130. The plurality of bottom ground pads BGNP are electrodes which transmit the ground signal to the plurality of sub pixels SP through the plurality of side ground lines GSRL and the plurality of top ground pads TGNP.

At this time, the plurality of bottom ground pads BGNP may also be disposed so as to correspond to the first bottom pad area BPA1. Each of the plurality of bottom ground pads BGNP may be disposed so as to correspond to each of the plurality of top ground pads TGNP and thereafter, the top ground pads TGNP and the bottom ground pads BGNP which overlap each other may be electrically connected through the side ground line GSRL.

Referring to FIG. 8, each of the plurality of bottom ground pads BGNP includes a plurality of bottom ground pad electrodes. For example, each of the plurality of bottom ground pads BGNP may include a first bottom ground pad electrode BGNPEa, a second bottom ground pad electrode BGNPEb, and a third bottom ground pad electrode BGNPEc. The first bottom ground pad electrode BGNPEa is formed of the same material as the first bottom pad electrode BPEa on the same layer as the first bottom pad electrode BPEa. The second bottom ground pad electrode BGNPEb is formed of the same material as the second bottom pad electrode BPEb on the same layer as the second bottom pad electrode BPEb. The third bottom ground pad electrode BGNPEc is formed of the same material as the third bottom pad electrode BPEc on the same layer as the third bottom pad electrode BPEc.

Referring to FIGS. 6 and 8 together, a side insulating layer 150 which covers the plurality of side lines SRL and the plurality of side ground lines GSRL is disposed. The side insulating layer 150 may be formed on the top surface of the first substrate 110, the side surface of the first substrate 110, the side surface of the second substrate 130, and the rear surface of the second substrate 130 so as to cover the plurality of side lines SRL and the plurality of side ground lines GSRL. The side insulating layer 150 may protect the plurality of side lines SRL and the plurality of side ground lines GSRL.

In the meantime, when the plurality of side lines SRL and the plurality of side ground lines GSRL are formed of a metal material, there may be a problem in that the external light is reflected from the plurality of side lines SRL and the plurality of side ground lines GSRL or light emitted from the light emitting diode LED is reflected from the plurality of side lines SRL and the plurality of side ground lines GSRL to be seen by the user. Therefore, the side insulating layer 150 is configured to include a black material to suppress reflection of the external light. For example, the side insulating layer 150 may be formed by a pad printing method using an insulating material including a black material, for example, a black ink.

A seal member 160 which covers the side insulating layer 150, the plurality of side lines SRL and the plurality of side ground lines GSRL is disposed. The seal member 160 is disposed so as to enclose the side surface of the display device 100 to protect the display device 100 from external impacts, moisture, and oxygen. For example, the seal member 160 may be formed of polyimide (PI), poly urethane, epoxy, or acryl based insulating material, but is not limited thereto.

An optical film MF is disposed on the seal member 160, the side insulating layer 150, and the protection layer 190. The optical film MF may be a functional film which implements a higher quality of images while protecting the display device 100. For example, the optical film MF may include an anti-scattering film, an anti-glare film, an anti-reflecting film, a low-reflecting film, an Oled transmittance controllable film, or a polarizer, but is not limited thereto.

In the meantime, even though an adhesive layer may be further disposed between the optical film MF and the seal member 160 and the side insulating layer 150 and the protection layer 190, in FIGS. 6 and 8, the adhesive layer is not illustrated for the sake of convenience of illustration. Alternatively, the optical film MF may also be defined to include an adhesive layer disposed there below.

An edge of the seal member 160 and an edge of the optical film MF may be disposed on the same line. The optical film MF having a larger size is attached above the first substrate 110 during the manufacturing process of the display device 100 and the seal member 160 which covers the side insulating layer 150 may be formed. Thereafter, a laser is irradiated on the seal member 160 and the optical film MF so as to correspond to an edge of the display device 100 to cut portions of the seal member 160 and the optical film MF. Accordingly, the size of the display device 100 is adjusted by an outer periphery cutting process of the seal member 160 and the optical film MF and the edge of the display device 100 may be formed to be flat.

Hereinafter, a COF pad area BPA3 of the display device according to the exemplary embodiment of the present disclosure will be described in more detail with reference to FIG. 9.

FIG. 9 is a cross-sectional view of a second substrate taken along line A-A′ of FIG. 4 according to one embodiment. In FIG. 9, for the convenience of illustration, the flexible film COF is not illustrated, but the COF pad BPAD3 is illustrated. In FIG. 9, for the convenience of illustration, it is illustrated that the positions of the second substrate 130 and the COF pad BPAD3 are inverted and the second substrate 130 is disposed at the bottom in the drawing.

Referring to FIG. 9, a plurality of COF pads BPAD3 are disposed in the COF pad area BPA3.

Each of the plurality of COF pads BPAD3 may be formed by a plurality of conductive layers. For example, each of the plurality of COF pads BPAD3 may include a first COF pad electrode BPE3a, a second COF pad electrode BPE3b, and a third COF pad electrode BPE3c.

In FIG. 9, it is illustrated that the COF pad BPAD3 is disposed on the second substrate 130 for the convenience of illustration and the first COF pad electrode BPE3a, the second COF pad electrode BPE3b, and the third COF pad electrode BPE3c are sequentially disposed above the second substrate 130.

However, the second substrate 130 illustrated in FIG. 9 is disposed upside down to be bonded to the first substrate 110. Therefore, in the bonded state of the second substrate 130 and the first substrate 110, the plurality of COF pads BPAD3 may be disposed below the second substrate 130. Further, the first COF pad electrode BPE3a, the second COF pad electrode BPE3b, and the third COF pad electrode BPE3c may be sequentially disposed below the second substrate 130.

Hereinafter, it is described based on a state in which the second substrate 130 is bonded to the first substrate 110 and it is described that the first COF pad electrode BPE3a, the second COF pad electrode BPE3b, and the third COF pad electrode BPE3c are sequentially disposed below the second substrate 130.

The first COF pad electrode BPE3a is disposed below the second substrate 130.

The first COF pad electrode BPE3a may be disposed on a same layer as the first bottom pad electrode BPEa and formed of the same material as the first bottom pad electrode BPEa. For example, the first COF pad electrode BPE3a may be configured by copper (Cu), aluminum (Al), molybdenum (Mo), nickel (Ni), titanium (Ti), chrome (Cr), or an alloy thereof, but is not limited thereto.

The second COF pad electrode BPE3b is disposed below the first COF pad electrode BPE3a. The second COF pad electrode BPE3b may be in contact with one surface of the first COF pad electrode BPE3a exposed by the first insulating layer 131.

The second COF pad electrode BPE3b may be disposed on a same layer as the second bottom pad electrode BPEb and formed of the same material as the second bottom pad electrode BPEb. For example, the second COF pad electrode BPE3b may be configured by a conductive material, such as copper (Cu), aluminum (Al), molybdenum (Mo), nickel (Ni), titanium (Ti), chrome (Cr), or an alloy thereof, but is not limited thereto.

The third COF pad electrode BPE3c is disposed below the second COF pad electrode BPE3b. The third COF pad electrode BPE3c may be in contact with one surface of the second COF pad electrode BPE3b exposed by the second insulating layer 132.

The third COF pad electrode BPE3c may be formed of the same material as the third bottom pad electrode BPEc. For example, the third COF pad electrode BPE3c may be formed of a material which is hardly corroded even when in contact with air or moisture in order to suppress the corrosion of the second COF pad electrode BPE3b. For example, the third COF pad electrode BPE3c may be formed of a conductive material, for example, a transparent conductive material, such as indium tin oxide (ITO) or indium zinc oxide (IZO), but is not limited thereto.

The plurality of COF pads BPAD3 may be electrically connected to the plurality of flexible films COF through the third COF pad electrode BPE3c, among the plurality of conductive layers which configures the plurality of COF pads BPAD3, respectively. That is, the plurality of COF pads BPAD3 may be electrically connected to an external module through the third COF pad electrode BPE3c.

The third COF pad electrode BPE3c extends from one surface of the second COF pad electrode BPE3b to cover a side surface and a portion of one surface of the second insulating layer 132.

In the meantime, the third insulating layer 133 may not be disposed between adjacent COF pads BPAD3, among the COF pad areas BPA3, to make easy contact of the COF pad BPAD3 and the flexible film COF. For example, one flexible film COF may be electrically connected to the plurality of COF pads BPAD3 through the adhesive layer. However, when an insulating layer with a large thickness is disposed between adjacent COF pads BPAD3, a step is generated between the plurality of COF pads BPAD3 and the flexible film COF to cause a contact failure of the plurality of COF pads BPAD3 and the flexible film COF. Therefore, the third insulating layer 133 may not be disposed between adjacent COF pads BPAD3, among the COF pad areas BPA3, but is not limited thereto.

Even though it is not illustrated in FIG. 9, the plurality of COF pads BPAD3 may be electrically connected to the plurality of flexible films COF through the third COF pad electrode BPE3c, among the plurality of conductive layers which configures the plurality of COF pads BPAD3.

The plurality of COF pads BPAD3 may be connected to the plurality of flexible films COF through the adhesive layer. For example, the adhesive layer may be an anisotropic conductive film (ACF) or a conductive paste. Further, for example, the plurality of flexible films COF may be electrically connected to the plurality of COF pads BPAD3 of the second substrate 130 by heat and a pressure.

Hereinafter, a bottom power line will be described in detail with reference to FIG. 10.

FIG. 10 is a cross-sectional view of a second substrate taken along lines B-B′ and C-C′ of FIG. 4 according to one embodiment. FIG. 10 is a cross-sectional view of a first bottom line area BLA1 and a second bottom line area BLA2. In FIG. 10, it is illustrated that positions of the second substrate 130 and components below the second substrate 130 are inverted so as to dispose the second substrate 130 is disposed at the bottom, for the convenience of illustration.

Referring to FIG. 10, a bottom high potential power line BVL1, a bottom auxiliary high potential power line BAVL1, a bottom auxiliary low potential power line BAVL2, and a plurality of bottom data link lines BDL are disposed in the first bottom line area BLA1.

In FIG. 10, for the convenience of illustration, it is illustrated that a bottom high potential power line BVL1, a bottom auxiliary high potential power line BAVL1, a bottom auxiliary low potential power line BAVL2, and a plurality of bottom data link lines BDL are disposed on the second substrate 130.

However, the second substrate 130 illustrated in FIG. 10 is disposed upside down to be bonded to the first substrate 110. Therefore, in the bonded state of the second substrate 130 and the first substrate 110, the bottom high potential power line BVL1, the bottom auxiliary high potential power line BAVL1, the bottom auxiliary low potential power line BAVL2, and the plurality of bottom data link lines BDL may be disposed below the second substrate 130.

Hereinafter, it is described based on a state in which the second substrate 130 is bonded to the first substrate 110 and it is described that the bottom high potential power line BVL1, the bottom auxiliary high potential power line BAVL1, the bottom auxiliary low potential power line BAVL2, and the plurality of bottom data link lines BDL are disposed below the second substrate 130.

The bottom high potential power line BVL1 is disposed below the second substrate 130.

The bottom high potential power line BVL1 may be disposed on a same layer as the first bottom pad electrode BPEa and the first COF pad electrode BPE3a and formed of the same material as the first bottom pad electrode BPEa and the first COF pad electrode BPE3a. For example, the bottom high potential power line BVL1 may be configured by a conductive material, such as copper (Cu), aluminum (Al), molybdenum (Mo), nickel (Ni), titanium (Ti), chrome (Cr), or an alloy thereof, but is not limited thereto.

The first insulating layer 131 is disposed below the bottom high potential power line BVL1. The first insulating layer 131 may include a plurality of openings disposed in a position overlapping the plurality of bottom auxiliary high potential power lines BAVL1 to be described below. In the meantime, the first insulating layer 131 is disposed so as to overlap the plurality of bottom data link line BDL to insulate the bottom high potential power line BVL1 from the plurality of bottom data link lines BDL.

The plurality of bottom auxiliary high potential power lines BAVL1 and the plurality of bottom data link lines BDL are disposed below the first insulating layer 131.

First, referring to C-C′ of FIG. 10, the plurality of bottom auxiliary high potential power lines BAVL1 is disposed below the first insulating layer 131.

The plurality of bottom auxiliary high potential power lines BAVL1 may be in contact with one surface of the bottom high potential power line BVL1 exposed by the first insulating layer 131. For example, the plurality of bottom auxiliary high potential power lines BAVL1 may be disposed to be spaced apart from each other between the flexible films COF and alternately disposed with the flexible film COF along the row direction. Therefore, each of the plurality of bottom auxiliary high potential power lines BAVL1 may be disposed to overlap the bottom high potential power line BVL1 disposed between the adjacent flexible films COF. For example, the first insulating layer 131 and the plurality of bottom auxiliary high potential power lines BAVL1 are disposed below the bottom high potential power line BVL1 and the first insulating layer 131 may be disposed in an area other than between the flexible films COF. Therefore, the plurality of bottom auxiliary high potential power lines BAVL1 may be in contact with the bottom high potential power line BVL1 in an area between the flexible films COF in which the first insulating layer 131 is open.

Therefore, the plurality of bottom auxiliary high potential power lines BAVL1 is in contact with the bottom high potential power line BVL1 to minimize or at least reduce voltage drop and voltage deviation.

The plurality of bottom auxiliary high potential power lines BAVL1 may be disposed on a same layer as the second bottom pad electrode BPEb and the second COF pad electrode BPE3b and formed of the same material as the second bottom pad electrode BPEb and the second COF pad electrode BPE3b. For example, the plurality of bottom auxiliary high potential power lines BAVL1 may be configured by a conductive material, such as copper (Cu), aluminum (Al), molybdenum (Mo), nickel (Ni), titanium (Ti), chrome (Cr), or an alloy thereof, but is not limited thereto.

A plurality of bottom data link lines BDL are disposed below the first insulating layer 131. The plurality of bottom data link lines BDL may be disposed on the same layer as the plurality of bottom auxiliary high potential power lines BAVL1.

Further, the plurality of bottom data link lines BDL may be disposed so as to overlap the bottom high potential power line BVL1. For example, the plurality of bottom data link lines BDL may be disposed so as to overlap the bottom high potential power line BVL1 with the first insulating layer 131 therebetween.

The plurality of bottom data link lines BDL may be disposed on a same layer as the plurality of bottom auxiliary high potential power lines BAVL1, the second bottom pad electrode BPEb and the second COF pad electrode BPE3b and formed of the same material as the plurality of bottom auxiliary high potential power lines BAVL1, the second bottom pad electrode BPEb and the second COF pad electrode BPE3b. For example, the plurality of bottom data link lines BDL may be configured by a conductive material such as copper (Cu), aluminum (Al), molybdenum (Mo), nickel (Ni), titanium (Ti), chrome (Cr), or an alloy thereof, but is not limited thereto.

The second insulating layer 132 and the third insulating layer 133 are disposed below the plurality of bottom data link lines BDL and the plurality of bottom auxiliary high potential power lines BAVL1.

The second insulating layer 132 and the third insulating layer 133 are disposed so as to overlap the plurality of bottom auxiliary low potential power lines BAVL2 to be described below to insulate the plurality of bottom data link lines BDL and the plurality of bottom auxiliary high potential power lines BAVL1 from the plurality of bottom auxiliary low potential power lines BAVL2.

The plurality of bottom auxiliary low potential power lines BAVL2 may be disposed below the third insulating layer 133. The plurality of bottom auxiliary low potential power lines BAVL2 may be disposed on a layer different from those of the plurality of bottom auxiliary high potential power lines BAVL1 and the plurality of bottom data link lines BDL.

In the meantime, each of the plurality of bottom auxiliary low potential power lines BAVL2 may overlap the plurality of bottom data link lines BDL. Further, the plurality of bottom auxiliary low potential power lines BAVL2 may be disposed to overlap a portion of the bottom high potential power line BVL1 disposed below the plurality of bottom data link lines BDL. For example, the plurality of bottom auxiliary low potential power lines BAVL2 may be disposed to overlap the plurality of bottom data link lines BDL with the second insulating layer 132 and the third insulating layer 133 therebetween. The plurality of bottom auxiliary low potential power lines BAVL2 may also be disposed to overlap the bottom high potential power line BVL1 with the first insulating layer 131, the second insulating layer 132, and the third insulating layer 133 therebetween.

Further, the plurality of bottom auxiliary low potential power line BAVL2 and the plurality of bottom auxiliary high potential power lines BAVL1 may be alternately disposed along the row direction.

The plurality of bottom auxiliary low potential power lines BAVL2 may be disposed on a same layer as the third bottom pad electrode BPEc and the third COF pad electrode BPE3c and formed of the same material as the third bottom pad electrode BPEc and the third COF pad electrode BPE3c. For example, the plurality of bottom auxiliary low potential power line BAVL2 may be formed of a conductive material, for example, a transparent conductive material, such as indium tin oxide (ITO) or indium zinc oxide (IZO), but is not limited thereto.

Referring to B-B′ of FIG. 10, the bottom low potential power line BVL2 is disposed in the second bottom line area BLA2.

For the convenience of illustration, in FIG. 10, it is illustrated that the bottom low potential power line BVL2 is disposed on the second substrate 130 and the second substrate 130 illustrated in FIG. 10 is located upside down to be bonded to the first substrate 110. Therefore, in a state in which the second substrate 130 and the first substrate 110 are bonded, the bottom low potential power line BVL2 may be disposed below the second substrate 130.

Hereinafter, it is described based on a state in which the second substrate 130 is bonded to the first substrate 110, and it is described that the bottom low potential power line BVL2 is disposed below the second substrate 130.

The bottom low potential power line BVL2 includes a first bottom low potential power line BVL2a, a second bottom low potential power line BVL2b, and a third bottom low potential power line BVL2c.

The first bottom low potential power line BVL2a is disposed below the second substrate 130.

The first bottom low potential power line BVL2a may be disposed on a same layer as the first bottom pad electrode BPEa and the first COF pad electrode BPE3a and formed of the same material as the first bottom pad electrode BPEa and the first COF pad electrode BPE3a. For example, the first bottom low potential power line BVL2a may be configured by a conductive material, such as copper (Cu), aluminum (Al), molybdenum (Mo), nickel (Ni), titanium (Ti), chrome (Cr), or an alloy thereof, but is not limited thereto.

The first insulating layer 131 is disposed below the first bottom low potential power line BVL2a and the second bottom low potential power line BVL2b may be disposed below the first insulating layer 131.

The second bottom low potential power line BVL2b may be in contact with one surface of the first bottom low potential power line BVL2a exposed by the first insulating layer 131. For example, the first insulating layer 131 and the second bottom low potential power line BVL2b are disposed below the first bottom low potential power line BVL2a and the first insulating layer 131 may be disposed in an area excluding the second bottom line area BLA2. Therefore, the second bottom low potential power line BVL2b may be in contact with the first bottom low potential power line BVL2a in the second bottom line area BLA2.

The second bottom low potential power line BVL2b may be disposed on a same layer as the second bottom pad electrode BPEb and the second COF pad electrode BPE3b and formed of the same material as the second bottom pad electrode BPEb and the second COF pad electrode BPE3b. For example, the second bottom low potential power line BVL2b may be configured by a conductive material, such as copper (Cu), aluminum (Al), molybdenum (Mo), nickel (Ni), titanium (Ti), chrome (Cr), or an alloy thereof, but is not limited thereto.

The second insulating layer 132 and the third insulating layer 133 are sequentially disposed below the second bottom low potential power line BVL2b and the third bottom low potential power line BVL2c may be disposed below the third insulating layer 133.

The third bottom low potential power line BVL2c may be in contact with the front surface of the second bottom low potential power line BVL2b exposed by the second insulating layer 132 and the third insulating layer 133. For example, the second insulating layer 132, the third insulating layer 133, and the third bottom low potential power line BVL2c are sequentially disposed below the second bottom low potential power line BVL2b and each of the second insulating layer 132 and the third insulating layer 133 may be disposed in an area excluding the second bottom line area BLA2. Therefore, the third bottom low potential power line BVL2c may be in contact with the second bottom low potential power line BVL2b in the second bottom line area BLA2.

The third bottom low potential power line BVL2c may be disposed on a same layer as the third bottom pad electrode BPEc and formed of the same material as the third bottom pad electrode BPEc and the third COF pad electrode BPE3c. For example, the third bottom low potential power line BVL2c may be formed of a conductive material, for example, a transparent conductive material, such as indium tin oxide (ITO) or indium zinc oxide (IZO), but is not limited thereto.

Referring to B-B′ of FIG. 10, a plurality of bottom ground lines BGNL are disposed in the COF pad area BPA3 and the first bottom line area BLA1. The plurality of bottom ground lines BGNL may be in contact with the plurality of bottom low potential power lines BVL2 disposed in the second bottom line area BLA2.

For the convenience of illustration, in FIG. 10, it is illustrated that the bottom ground line BGNL is disposed on the second substrate 130 but the second substrate 130 illustrated in FIG. 10 is located upside down to be bonded to the first substrate 110. Therefore, in a state in which the second substrate 130 and the first substrate 110 are bonded, the bottom ground line BGNL may be disposed below the second substrate 130.

Hereinafter, it is described based on a state in which the second substrate 130 is bonded to the first substrate 110, and it is described that the bottom ground line BGNL is disposed below the second substrate 130.

Each of the plurality of bottom ground lines BGNL includes a first bottom ground line BGNLa, a second bottom ground line BGNLb, and a third bottom ground line BGNLc.

The first bottom ground line BGNLa is disposed below the second substrate 130.

The first bottom ground line BGNLa may be disposed on a same layer as the first bottom low potential power line BVL2a and formed of the same material as the first bottom low potential power line BVL2a. For example, the first bottom ground line BGNLa may be integrally formed with the first bottom low potential power line BVL2a, but is not limited thereto. The first bottom ground line BGNLa may be configured by a conductive material such as copper (Cu), aluminum (Al), molybdenum (Mo), nickel (Ni), titanium (Ti), chrome (Cr), or an alloy thereof, but is not limited thereto.

The first insulating layer 131 may be disposed below the first bottom ground line BGNLa and the second bottom ground line BGNLb may be disposed below the first insulating layer 131.

The second bottom ground line BGNLb may be in contact with one surface of the first bottom ground line BGNLa exposed by the first insulating layer 131.

The second bottom ground line BGNLb may be disposed on a same layer as the second bottom low potential power line BVL2b and formed of the same material as the second bottom low potential power line BVL2b. For example, the second bottom ground line BGNLb may be integrally formed with the second bottom low potential power line BVL2b, but is not limited thereto. The second bottom ground line BGNLb may be configured by a conductive material such as copper (Cu), aluminum (Al), molybdenum (Mo), nickel (Ni), titanium (Ti), chrome (Cr), or an alloy thereof, but is not limited thereto.

The third bottom ground line BGNLc may be disposed below the second bottom ground line BGNLb.

The third bottom ground line BGNLc may be in contact with one surface of the second bottom ground line BGNLb exposed by the second insulating layer 132 and the third insulating layer 133.

The third bottom ground line BGNLc may be disposed on a same layer as the third bottom low potential power line BVL2c and formed of the same material as the third bottom low potential power line BVL2c. For example, the third bottom ground line BGNLc may be integrally formed with the third bottom low potential power line BVL2c, but is not limited thereto. For example, the third bottom ground line BGNLc may be formed of a conductive material, for example, a transparent conductive material, such as indium tin oxide (ITO) or indium zinc oxide (IZO), but is not limited thereto.

The plurality of bottom ground lines BGNL may be connected to the plurality of bottom ground pads BGNP. In the meantime, even though it is not illustrated in FIG. 10, the display device 100 may further include a cover bottom which supports the display panel PN. At this time, the plurality of bottom ground lines BGNL may be earthed to the bottom cover through a conductive tape. For example, the conductive tape is disposed in the first edges EG1 of the first substrate 110 and the second substrate 130 and the plurality of bottom ground lines BGNL may be earthed to a ground voltage through the conductive tape.

In the meantime, when a plurality of first pads to which a high potential voltage is applied is disposed in a first edge of the display device and a plurality of second pads to which a low potential voltage is applied is disposed in a second edge, a path for discharging a static electricity is not formed in the first edge of the display device. Therefore, the first edge of the display device may be vulnerable to the static electricity. Specifically, when a data pad is disposed in an outermost peripheral area, among the plurality of first pads of the display device, the static electricity may not be discharged due to a wiring capacity limitation. Therefore, a static electricity generated in the data pad disposed at the corner portion of the first pad area may enter the data line and overcurrent may flow in the data line, and the data line may be shorted or open. Therefore, a burnt phenomenon of the display panel may occur.

In the meantime, when the display device is formed by bonding the first substrate and the second substrate, a side line is formed on the side surfaces of the first substrate and the second substrate to electrically connect the plurality of driving transistors above the first substrate and the plurality of wiring lines below the second substrate. At this time, when the static electricity occurs in the display device, the static electricity may enter the side line through a side insulating layer. For example, the side insulating layer may have a small thickness between a plurality of adjacent pads and the static electricity may enter the side line through the side insulating layer with a small thickness. Therefore, an anti-static electricity circuit which discharges the static electricity entering the display device is disposed above the first substrate. However, in order to reduce the bezel of the display panel, a plurality of driving transistors for driving a plurality of pixels of the display device is disposed on the first substrate and only a plurality of wiring lines which is connected to the plurality of driving transistors disposed on the first substrate may be disposed below the second substrate. In this case, it is difficult to place a separate circuit configuration below the second substrate. Therefore, it may be difficult to place an anti-static electricity circuit below the second substrate. Accordingly, when a static electricity is generated on a rear surface of the second substrate, a path for dissipating the static electricity is not formed to be vulnerable to the static electricity. Therefore, the static electricity generated on the rear surface of the second substrate causes the damage of the driving transistors disposed above the first substrate through the side line to cause the defect of the display device.

Accordingly, in the display device 100 according to the exemplary embodiment of the present disclosure, a top ground pad TGNP and a bottom ground pad BGNP are disposed in the first top pad area TPA1 of the first substrate 110 and the first bottom pad area BPA1 of the second substrate 130, respectively. Specifically, the top ground pad TGNP and the bottom ground pad BGNP may be disposed to be adjacent to an outer periphery of the first substrate 110 and an outer periphery of the second substrate 130 more than the plurality of first top pads TPAD1 and the plurality of first bottom pads BPAD1. Accordingly, when the static electricity enters the corner of the first top pad area TPA1 and the first bottom pad area BPA1, a separate path to allow the electricity to flow through the top ground pad TGNP and the bottom ground pad BGNP may be formed. Accordingly, in the display device 100 according to the exemplary embodiment of the present disclosure, overcurrent which may be generated in the first top pad area TPA1 and the first bottom pad area BPA1 may be suppressed.

Further, in the display device 100 according to the exemplary embodiment of the present disclosure, the top ground pad TGNP and the bottom ground pad BGNP are disposed in the first top pad area TPA1 and the first bottom pad area BPA1, respectively. Therefore, the static electricity may be dissipated without placing a separate anti-static electricity circuit. Therefore, the top ground pad TGNP and the bottom ground pad BGNP discharge the static electricity which is generated by the external contact or internally generated to improve the reliability of the display device 100. Accordingly, in the display device 100 according to the exemplary embodiment of the present disclosure, the damage of the plurality of driving transistors DT and the light emitting diode LED due to the static electricity may be suppressed.

The exemplary embodiments of the present disclosure can also be described as follows:

According to an aspect of the present disclosure, there is provided a display device. The display device comprises a first substrate; a plurality of top pads disposed on the first substrate; a second substrate disposed below the first substrate; a plurality of bottom pads disposed below the second substrate; a plurality of side lines which may be disposed on a side surface of the first substrate and a side surface of the second substrate to connect the plurality of top pads and the plurality of bottom pads; and a plurality of ground pads which may be disposed in a first edge of the first substrate and a first edge of the second substrate, wherein the plurality of top pads includes: a plurality of first pads disposed in a first pad area of the first edge of the first substrate; and a plurality of second pads disposed in a second pad area of a second edge of the first substrate, the plurality of bottom pads includes: a plurality of first pads disposed in a first pad area of the first edge of the second substrate; and a plurality of second pads disposed in a second pad area of a second edge of the second substrate, wherein a high potential voltage is applied to the plurality of first pads of the plurality of top pads and the plurality of bottom pads and a low potential voltage is applied to the plurality of second pads of the plurality of top pads and the plurality of bottom pads, and the plurality of ground pads is disposed in the first edge of the first substrate and the first edge of the second substrate to be spaced apart from each other with the plurality of first pads therebetween of the plurality of top pads and the plurality of bottom pads.

The display device may further comprise a plurality of side ground lines disposed on the side surface of the first substrate and the side surface of the second substrate, wherein each of the plurality of ground pads may include a top ground pad which may be disposed on the first substrate and is formed with the same structure as the plurality of top pads; and a bottom ground pad which may be disposed below the second substrate and is formed with the same structure as the plurality of bottom pads, and the plurality of side ground lines may connect the top ground pad and the bottom ground pad.

The display device may further comprise a high potential power line and a low potential power line disposed below the second substrate, wherein the second substrate may include the first pad area which may be disposed in the first edge of the second substrate and in which the plurality of first pads of the plurality of bottom pads is disposed; the second pad area which may be disposed in the second edge of the second substrate and in which the plurality of second pads of the plurality of bottom pads is disposed; a line area disposed between the first pad area and the second pad area; and a COF pad area disposed between the first pad area and the second pad area, and the line area may include a first line area disposed between the COF pad area and the first pad area; and a second line area disposed between the COF pad area and the second pad area, the high potential power line may be disposed in the first line area to be connected to the plurality of first pads of the plurality of bottom pads, and the low potential power line may be disposed in the second line area to be connected to the plurality of second pads of the plurality of bottom pads.

The display device may further comprise a plurality of ground lines which may be disposed at an outside of the high potential power line in the first line area, wherein the plurality of ground lines may extend to the first edge of the second substrate to be connected to the plurality of ground pads.
the plurality of ground lines may be in contact with the low potential power line.

The low potential power line may include: a first low potential power line disposed below the second substrate; a second low potential power line disposed below the first low potential power line; and a third low potential power line disposed below the second low potential power line.

Each of the plurality of ground lines may include: a first ground line disposed on a same layer as the first low potential power line; a second ground line disposed on a same layer as the second low potential power line; and a third ground line disposed on a same layer as the third low potential power line.

The first ground line may be integrally formed with the first low potential power line, the second ground line may be integrally formed with the second low potential power line, and the third ground line may be integrally formed with the third low potential power line.

The display device may further comprise a plurality of data link lines which may be disposed in the first line area to extend to the COF pad area; and a plurality of auxiliary low potential power lines which may overlap the plurality of data link lines below the plurality of data link lines, wherein the plurality of data link lines and the plurality of auxiliary low potential power lines may be disposed below the high potential power lines to overlap a portion of the high potential power line.

The plurality of auxiliary low potential power lines may extend to the second line area to be electrically connected to the low potential power line.

The display device may further comprise a plurality of auxiliary high potential power lines which may be disposed below the high potential power line to be in contact with the high potential power line, wherein the plurality of auxiliary high potential power lines may be disposed alternately with the plurality of auxiliary low potential power lines.

The plurality of auxiliary high potential power lines and the plurality of auxiliary low potential power lines may be disposed on different layers.

The plurality of data link lines and the plurality of auxiliary high potential power lines may be disposed on the same layer, the high potential power line may be disposed above the plurality of data link lines and the plurality of auxiliary high potential power lines, and the plurality of auxiliary low potential power lines may be disposed below the plurality of data link lines and the plurality of auxiliary high potential power lines.

The display device may further comprise an inorganic insulating layer disposed between the plurality of data link lines and the high potential power line; and an organic insulating layer disposed between the plurality of data link lines and the plurality of auxiliary high potential power lines, and the plurality of auxiliary low potential power lines.

Each of the plurality of bottom pads may include a first bottom pad electrode disposed below the second substrate; a second bottom pad electrode disposed below the first bottom pad electrode; and a third bottom pad electrode disposed below the second bottom pad electrode. The high potential power line may be disposed on the same layer as the first bottom pad electrode, the plurality of data link lines and the plurality of auxiliary high potential power lines may be disposed on the same layer as the second bottom pad electrode, and the plurality of auxiliary low potential power lines may be disposed on the same layer as the third bottom pad electrode.

The third bottom pad electrode may be formed of indium tin oxide (ITO).

The more adjacent to the first pad area, the smaller widths of the plurality of auxiliary high potential power lines, and the more adjacent to the first pad area, the larger widths of the plurality of auxiliary low potential power lines.

A width of the low potential power line may correspond to a width of the second pad area and a width of the high potential power line may correspond to a width of the first pad area.

The display device may further comprise a plurality of transistors disposed on the first substrate; a plurality of reflective electrodes disposed on the plurality of transistors; a plurality of light emitting diodes disposed on the plurality of reflective electrodes; and a connection electrode which may be connected to the plurality of light emitting diodes, wherein each of the plurality of top pads may include a first top pad electrode disposed on the same layer as the plurality of transistors; a second top pad electrode disposed on the same layer as the plurality of reflective electrodes; and a third top pad electrode disposed on the same layer as the connection electrode.

The display device may further comprise a conductive tape disposed at an outside of the plurality of side ground lines; and a cover bottom which may be in contact with the conductive tape.

the plurality of ground pads may be disposed to be adjacent to an outer periphery of the first substrate and an outer periphery of the second substrate more than the plurality of first pads of the plurality of top pads and the plurality of bottom pads.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate;
a plurality of top pads on the first substrate;
a second substrate below the first substrate;
a plurality of bottom pads below the second substrate;
a plurality of side lines on a side surface of the first substrate and a side surface of the second substrate, the plurality of side lines connecting the plurality of top pads and the plurality of bottom pads; and
a plurality of ground pads in a first edge of the first substrate and a first edge of the second substrate,
wherein the plurality of top pads includes:
a plurality of first pads in a first pad area of the first edge of the first substrate; and
a plurality of second pads in a second pad area of a second edge of the first substrate,
the plurality of bottom pads includes:
a plurality of first pads in a first pad area of the first edge of the second substrate; and
a plurality of second pads in a second pad area of a second edge of the second substrate,
wherein a high potential voltage is applied to the plurality of first pads of the plurality of top pads and the plurality of bottom pads and a low potential voltage is applied to the plurality of second pads of the plurality of top pads and the plurality of bottom pads, and the plurality of ground pads in the first edge of the first substrate and the first edge of the second substrate are spaced apart from each other with the plurality of first pads of the plurality of top pads and the plurality of bottom pads therebetween.

2. The display device according to claim 1, further comprising:
a plurality of side ground lines on the side surface of the first substrate and the side surface of the second substrate,
wherein each of the plurality of ground pads includes:
a top ground pad on the first substrate and having a same structure as the plurality of top pads; and
a bottom ground pad below the second substrate and having a same structure as the plurality of bottom pads,
wherein the plurality of side ground lines connect the top ground pad and the bottom ground pad.

3. The display device according to claim 1, further comprising:
a high potential power line and a low potential power line below the second substrate, wherein the second substrate includes:
the first pad area in the first edge of the second substrate and in which the plurality of first pads of the plurality of bottom pads are disposed;
the second pad area in the second edge of the second substrate and in which the plurality of second pads of the plurality of bottom pads are disposed;
a line area between the first pad area and the second pad area; and
a COF pad area between the first pad area and the second pad area, the line area including:
a first line area between the COF pad area and the first pad area; and
a second line area between the COF pad area and the second pad area,
wherein the high potential power line is in the first line area and connected to the plurality of first pads of the plurality of bottom pads, and the low potential power line is in the second line area and connected to the plurality of second pads of the plurality of bottom pads.

4. The display device according to claim 3, further comprising:
a plurality of ground lines outside of the high potential power line in the first line area,
wherein the plurality of ground lines extend to the first edge of the second substrate and are connected to the plurality of ground pads.

5. The display device according to claim 4, wherein the plurality of ground lines are in contact with the low potential power line.

6. The display device according to claim 4, wherein the low potential power line includes:
a first low potential power line below the second substrate;
a second low potential power line below the first low potential power line; and
a third low potential power line below the second low potential power line.

7. The display device according to claim 6, wherein each of the plurality of ground lines includes:
a first ground line on a same layer as the first low potential power line;
a second ground line on a same layer as the second low potential power line; and
a third ground line on a same layer as the third low potential power line.

8. The display device according to claim 7, wherein the first ground line is integrally formed with the first low potential power line, the second ground line is integrally formed with the second low potential power line, and the third ground line is integrally formed with the third low potential power line.

9. The display device according to claim 3, further comprising:
a plurality of data link lines in the first line area and extend to the COF pad area; and
a plurality of auxiliary low potential power lines overlapped with the plurality of data link lines below the plurality of data link lines,
wherein the plurality of data link lines and the plurality of auxiliary low potential power lines are below the high potential power line and overlap a portion of the high potential power line.

10. The display device according to claim 9, wherein the plurality of auxiliary low potential power lines extend to the second line area and are electrically connected to the low potential power line.

11. The display device according to claim 9, further comprising:
a plurality of auxiliary high potential power lines below the high potential power line and in contact with the high potential power line,
wherein the plurality of auxiliary high potential power lines are disposed alternately with the plurality of auxiliary low potential power lines.

12. The display device according to claim 11, wherein the plurality of auxiliary high potential power lines and the plurality of auxiliary low potential power lines are on different layers.

13. The display device according to claim 11, wherein the plurality of data link lines and the plurality of auxiliary high potential power lines are on a same layer, the high potential power line is above the plurality of data link lines and the plurality of auxiliary high potential power lines, and the plurality of auxiliary low potential power lines are below the plurality of data link lines and the plurality of auxiliary high potential power lines.

14. The display device according to claim 13, further comprising:
an inorganic insulating layer between the plurality of data link lines and the high potential power line; and
an organic insulating layer between the plurality of data link lines and the plurality of auxiliary high potential power lines, and the plurality of auxiliary low potential power lines.

15. The display device according to claim 14, wherein each of the plurality of bottom pads includes:
a first bottom pad electrode below the second substrate;
a second bottom pad electrode below the first bottom pad electrode; and
a third bottom pad electrode below the second bottom pad electrode,
wherein the high potential power line is on a same layer as the first bottom pad electrode, the plurality of data link lines and the plurality of auxiliary high potential power lines are on a same layer as the second bottom pad electrode, and the plurality of auxiliary low potential power lines are on a same layer as the third bottom pad electrode.

16. The display device according to claim 15, wherein the third bottom pad electrode is formed of indium tin oxide.

17. The display device according to claim 11, wherein the more adjacent to the first pad area, the smaller widths of the plurality of auxiliary high potential power lines, and the more adjacent to the first pad area, the larger widths of the plurality of auxiliary low potential power lines.

18. The display device according to claim 3, wherein a width of the low potential power line corresponds to a width of the second pad area and a width of the high potential power line corresponds to a width of the first pad area.

19. The display device according to claim 3, further comprising:
a plurality of transistors on the first substrate;
a plurality of reflective electrodes on the plurality of transistors;
a plurality of light emitting diodes on the plurality of reflective electrodes; and
a connection electrode connected to the plurality of light emitting diodes,
wherein each of the plurality of top pads includes:
a first top pad electrode on a same layer as the plurality of transistors;
a second top pad electrode on a same layer as the plurality of reflective electrodes; and
a third top pad electrode on a same layer as the connection electrode.

20. The display device according to claim 2, further comprising:
a conductive tape at an outside of the plurality of side ground lines; and
a cover bottom in contact with the conductive tape.

21. The display device according to claim 1, wherein the plurality of ground pads are adjacent to an outer periphery of the first substrate and an outer periphery of the second substrate more than the plurality of first pads of the plurality of top pads and the plurality of bottom pads.
